(19) United States
(12) Patent Application Publication
(10) Pub. No.: US 2026/0282580 A1
(43) Pub. Date: Sep. 17, 2026

(54) LIGHT RECEIVING ELEMENT AND DISTANCE MEASURING DEVICE

(71) Applicant: SONY SEMICONDUCTOR SOLUTIONS CORPORATION, KANAGAWA (JP)

(72) Inventors: YUHI YORIKADO, KANAGAWA (JP); SOZO YOKOGAWA, KANAGAWA (JP)

(21) Appl. No.: 19/166,844

(22) PCT Filed: Mar. 6, 2024
(86) PCT No.: PCT/JP2024/008545

§ 371 Date: Sep. 18, 2025

(30) Foreign Application Priority Data
Mar. 30, 2023 (JP) 2023-055901

(51) Int. Cl. H10F 39/00; G01S 7/481; G01S 17/08

(52) U.S. Cl. CPC H10F 39/8063; G01S 7/4816; G01S 17/08; H10F 39/8057

(57) ABSTRACT

The present technology relates to a light receiving element and a distance measuring device that prevent occurrence of a difference in sensitivity between charge accumulation units in a light receiving element including two or more charge accumulation units.

A photoelectric conversion unit that performs photoelectric conversion, first and second charge accumulation units that accumulate charge obtained by the photoelectric conversion unit, and an on-chip lens that collects incident light to the photoelectric conversion unit are included, and a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit. The present technology can be applied to, for example, a light receiving element included in a distance measuring device.

### TECHNICAL FIELD

The present technology relates to a light receiving element and a distance measuring device, and, for example, relates to a light receiving element and a distance measuring device that perform accurate distance measurement.

### BACKGROUND ART

In recent years, with the progress of semiconductor technology, miniaturization of distance measuring modules for measuring a distance to an object has progressed. This makes it possible to mount distance measuring modules on, for example, mobile terminals such as so-called smartphones, which are small information processing apparatuses having communication functions.

Generally, as a distance measuring method in distance measuring modules, there is a time of flight (TOF) method. In a ToF imaging element, reflected light, which is light radiated from a light source and reflected from an object, is subjected to photoelectric conversion in a photodiode. Signal charge generated by the photoelectric conversion is distributed to two floating diffusions (FDs) by a pair of alternately driven gate electrodes (see, for example, Patent Document 1).

### CITATION LIST

### Patent Document

Patent Document 1: Japanese Patent Application Laid-Open No. 2021-97214

### SUMMARY OF THE INVENTION

### Problems to be Solved by the Invention

A technique called pupil correction has been proposed as a technique for suppressing occurrence of sensitivity unevenness in an image called shading due to an increase in a difference between the amount of light incident on a pixel in a central portion of an angle of view of an imaging surface and the amount of light incident on a pixel at an end of the angle of view.

In a case where the pupil correction technology is applied to an imaging element having a structure in which signal charge generated by photoelectric conversion is distributed to two FDs by a pair of alternately driven gate electrodes as in the above-described ToF imaging element, there is a possibility that sensitivities in the two FDs become different from each other. It is desired to perform appropriate pupil correction for a ToF imaging element.

The present technology has been made in view of such circumstances, and enables appropriate pupil correction to be performed on a ToF imaging element.

### Solutions to Problems

A light receiving element according to an aspect of the present technology includes a photoelectric conversion unit that performs photoelectric conversion, first and second charge accumulation units that accumulate charge obtained by the photoelectric conversion unit, and an on-chip lens that collects incident light to the photoelectric conversion unit, in which a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.

A distance measuring device according to an aspect of the present technology includes a light emitting unit that emits irradiation light, and a light receiving element that receives reflected light, which is the light emitted from the light emitting unit and reflected from an object, in which the light receiving element includes a photoelectric conversion unit that performs photoelectric conversion, first and second charge accumulation units that accumulate charge obtained by the photoelectric conversion unit, and an on-chip lens that collects incident light to the photoelectric conversion unit, and a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.

In the light receiving element according to the aspect of the present technology, a photoelectric conversion unit that performs photoelectric conversion, first and second charge accumulation units that store charges obtained by the photoelectric conversion unit, and an on-chip lens that condenses incident light on the photoelectric conversion unit are included. A center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.

In the distance measuring device according to the aspect of the present technology, the light receiving element is included.

Note that the distance measuring device may be an independent device or an internal block included in an apparatus.

### BRIEF DESCRIPTION OF DRAWINGS

FIG. 1 is a block diagram illustrating a configuration example of a distance measuring module in an embodiment of the present disclosure.

FIG. 2 is a diagram illustrating a planar configuration example of a light receiving unit.

FIG. 3 is a diagram illustrating a circuit configuration example of a light receiving element.

FIG. 4 is a diagram illustrating a distance measuring operation.

FIG. 5 is a diagram illustrating a planar configuration example of the light receiving element.

FIG. 6 is a diagram illustrating a cross-sectional configuration example of the light receiving element.

FIG. 7 is a diagram illustrating another circuit configuration example of the light receiving element.

FIG. 8 is a diagram illustrating another planar configuration example of the light receiving element.

FIG. 9 is a diagram illustrating another circuit configuration example of the light receiving element.

FIG. 10 is a diagram illustrating another planar configuration example of the light receiving element.

FIG. 11 is a diagram illustrating another circuit configuration example of the light receiving element.

FIG. 12 is a diagram illustrating another planar configuration example of the light receiving element.

FIG. 13 is a diagram for explaining a light receiving element subjected to pupil correction.

FIG. 14 is a diagram for explaining another light receiving element subjected to the pupil correction.

FIG. 15 is a diagram for explaining a position to which incident light travels.

FIG. 16 is a diagram for explaining how to calculate the amount of correction.

FIG. 17 is a diagram for explaining a position of a light blocking film.

FIG. 18 is a diagram for explaining that PLS becomes equal.

FIG. 19 is another diagram for explaining that the PLS becomes equal.

FIG. 20 is a diagram illustrating an arrangement example of four charge accumulation units.

FIG. 21 is a diagram illustrating an arrangement example of 2 taps.

FIG. 22 is a diagram for explaining an arrangement example of I pixels and Q pixels and processing related to generation of a distance measurement image.

FIG. 23 is a diagram for explaining another arrangement example of the I pixels and the Q pixels and the processing related to the generation of a distance measurement image.

FIG. 24 is a diagram illustrating a configuration example of an electronic device.

FIG. 25 is a view depicting an example of a schematic configuration of an endoscopic surgery system.

FIG. 26 is a block diagram depicting an example of a functional configuration of a camera head and a CCU.

FIG. 27 is a block diagram depicting an example of schematic configuration of a vehicle control system.

FIG. 28 is an explanatory diagram illustrating an example of installation positions of an outside-vehicle information detecting section and an imaging section.

### MODE FOR CARRYING OUT THE INVENTION

A mode for carrying out the present technology (hereinafter referred to as an embodiment) will be described hereinafter.

### <Configuration of Distance Measuring Module>

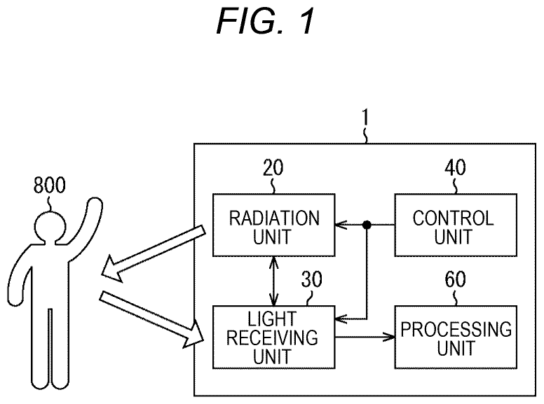

A schematic configuration of a distance measuring module (light receiving device) 1 according to the embodiment of the present disclosure will be described with reference to FIG. 1. FIG. 1 is a diagram illustrating a configuration example of the distance measuring module 1 according to the embodiment of the present disclosure. As illustrated in FIG. 1, the distance measuring module 1 includes a radiation unit 20, a light receiving unit 30, a control unit (radiation control unit) 40, and a processing unit 60.

The radiation unit 20 includes a light emitting diode (LED) light source (not illustrated) and an optical element (not illustrated). A wavelength of light to be radiated can be changed by appropriately selecting the LED light source. Here, the description will be given assuming that the radiation unit 20 radiates infrared light having a wavelength in a range of 780 nm to 1000 nm, for example, but is not limited to emitting such infrared light. The radiation unit 20 can radiate, onto an object 800, irradiation light whose brightness periodically varies in synchronization with a periodic signal such as a rectangular signal supplied from the control unit 40 described later.

The light receiving unit 30 receives reflected light reflected from the object 800. The light receiving unit 30 includes a condenser lens (not illustrated) and a plurality of light receiving elements 10 described later. The condenser lens has a function of collecting the received light to each light receiving element 10. The light receiving element 10 generates charge (for example, electrons) on the basis of intensity of the received light, drives a built-in transistor in synchronization with the periodic signal such as a rectangular signal supplied from the control unit 40 described later, and transfers the generated charge to a floating diffusion region FD or a charge accumulation unit MEM. Furthermore, the charge transferred to the floating diffusion region FD or the charge accumulation unit MEM is converted into a signal and finally transferred to the processing unit 60. Note that details of the light receiving element 10 will be described later.

The control unit 40 supplies a periodic signal to the radiation unit 20 and the light receiving unit 30, and controls radiation timings of the irradiation light and drive timings of the transistors. A frequency of the signal may be, for example, 5 to 20 megahertz (MHz), but is not limited to such a frequency. The control unit 40 controls the transistors such that the transistors operate at different timings, for example, differentially.

The processing unit 60 can acquire a signal from the light receiving unit 30 and acquire a distance to the object 800 by, for example, an indirect ToF (iToF) method on the basis of the acquired signal. Note that a method for calculating the distance will be described later.

### <Configuration Example of Light Receiving Unit>

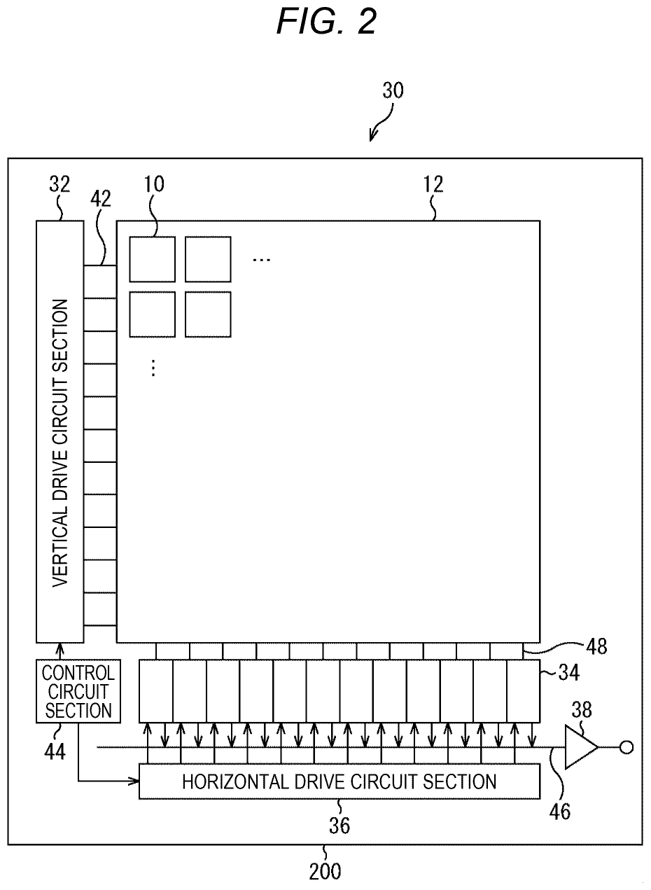

A planar configuration example of the light receiving unit 30 will be described with reference to FIG. 2. As illustrated in FIG. 2, the light receiving unit 30 includes, for example, a pixel array section 12, a vertical drive circuit section 32, column signal processing circuit sections 34, a horizontal drive circuit section 36, an output circuit section 38, a control circuit section 44, and the like provided on a semiconductor substrate 200 including silicon.

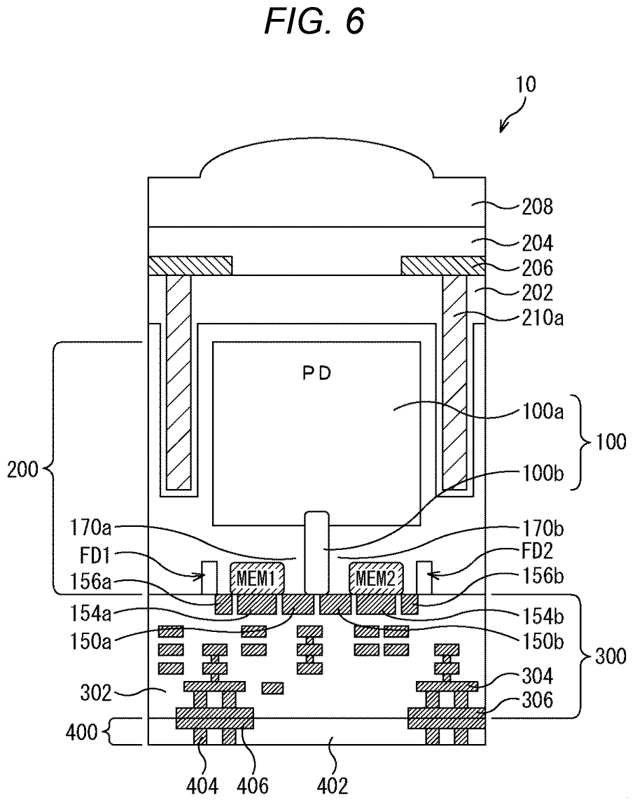

The pixel array section 12 includes the plurality of light receiving elements 10 arranged in two dimensions in a matrix (a matrix in a row direction and a column direction) on the semiconductor substrate 200. Each light receiving element 10 includes a photoelectric conversion unit (photodiode PD) (FIG. 6) that converts light into charge (for example, electrons), a plurality of pixel transistors (for example, metal-oxide-semiconductor (MOS) transistors) (FIG. 6), and the like. The pixel array section 12 includes a plurality of pixels that performs photoelectric conversion on incident light and that outputs signals according to charges obtained as a result of the photoelectric conversion. The plurality of pixel transistors includes transistors having various functions such as, for example, a transfer transistor, a selection transistor, a reset transistor, and an amplification transistor.

Here, the row direction refers to an arrangement direction of the light receiving elements 10 in a horizontal direction, and the column direction refers to an arrangement direction of the light receiving elements 10 in a vertical direction. The row direction is a left-and-right direction in FIG. 2, and the column direction is an up-and-down direction in FIG. 2. In the pixel array section 12, a pixel drive line 42 is provided for the matrix of the light receiving elements 10 in the row direction for each of rows, and a vertical signal line 48 is provided in the column direction for each of columns. For example, the pixel drive lines 42 transmit drive signals for driving at a time when signals are read from the light receiving elements 10.

The vertical drive circuit section 32 is formed by a shift register, an address decoder, and the like, for example, selects one of the pixel drive lines 42, supplies pulses for driving the light receiving elements 10 to the selected pixel drive line 42, and drives all the light receiving elements 10 simultaneously or in units of rows. For example, the vertical drive circuit section 32 selectively scans the light receiving elements 10 of the pixel array section 12 sequentially in the vertical direction (the up-and-down direction in FIG. 2) in units of rows, and supplies a pixel signal based on a charge generated according to the amount of light received by the photodiode PD of each light receiving element 10 to the column signal processing circuit section 34 described later through the vertical signal line 48.

The column signal processing circuit section 34 is provided for each column of the light receiving elements 10 and performs signal processing such as noise removal on signals output from the light receiving elements 10 of one row column by column. For example, each column signal processing circuit section 34 performs signal processing such as correlated double sampling (CDS) for removing fixed pattern noise specific to the light receiving elements 10 and analog-to-digital (AD) conversion.

The horizontal drive circuit section 36 includes, for example, a shift register, an address decoder, and the like, sequentially selects the column signal processing circuit sections 34 by sequentially outputting horizontal scanning pulses, and allows the column signal processing circuit sections 34 to output signals from to the horizontal signal lines 46.

The output circuit section 38 can perform signal processing on the signals sequentially supplied from the column signal processing circuit sections 34 described above via the horizontal signal lines 46 and output the processed signals. The output circuit section 38 may function as, for example, a functional unit that performs buffering, or may perform processing such as column variation correction and various types of digital signal processing. Note that the buffering refers to temporarily storing signals in order to compensate for differences in processing speed and transfer speed when the signals are exchanged.

The control circuit section 44 can receive an input clock and data specifying an operation mode and the like, and output data regarding internal information and the like of the light receiving elements 10. That is, the control circuit section 44 generates a clock signal and control signals that serve as references for operations of the vertical drive circuit section 32, the column signal processing circuit sections 34, the horizontal drive circuit section 36, and the like on the basis of a vertical synchronization signal, a horizontal synchronization signal, and a master clock. The control circuit section 44 then outputs the generated clock signal and control signals to the vertical drive circuit section 32, the column signal processing circuit sections 34, the horizontal drive circuit section 36, and the like.

### <Equivalent Circuit of Light Receiving Element>

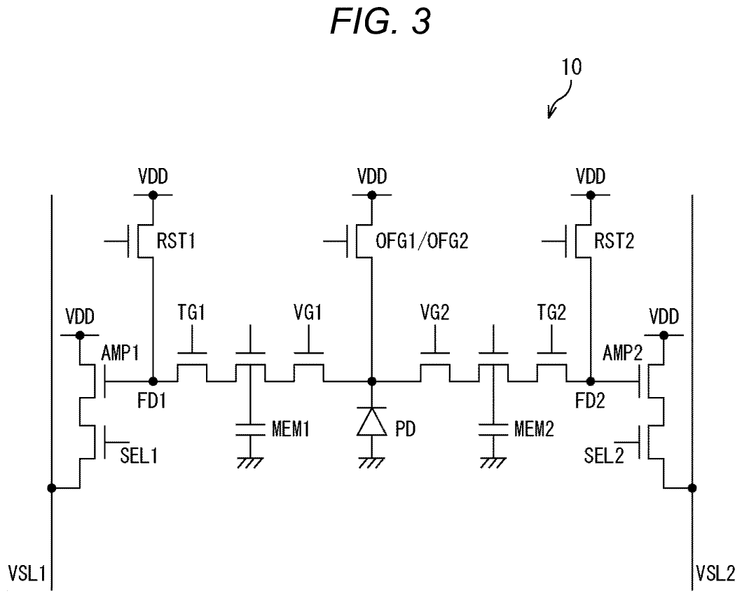

FIG. 3 is an equivalent circuit diagram of the light receiving element 10. As illustrated in FIG. 3, the light receiving element 10 includes a photodiode PD as a photoelectric conversion element (photoelectric conversion unit) that converts light into charge and a charge discharge transistor OFG (note that although the charge discharge transistor OFG is illustrated as one transistor in the equivalent circuit, the charge discharge transistor OFG may include a plurality of transistors electrically connected in parallel). Furthermore, the light receiving element 10 includes two distribution transistors VG, two charge accumulation units (a first charge accumulation unit and a second charge accumulation unit) MEM, two transfer transistors TG, two floating diffusion regions FD, two reset transistors RST, two amplification transistors AMP, and two selection transistors SEL.

As illustrated in FIG. 3, in the light receiving element 10, one of a source and a drain of the charge discharge transistor OFG is electrically connected to the photodiode PD that generates charge by receiving light. Furthermore, another of the source and the drain of the charge discharge transistor OFG is electrically connected to a power supply circuit (power supply potential VDD). The charge discharge transistor OFG can then be brought into a conductive state according to a voltage applied to a gate thereof, and discharge the charge accumulated in the photodiode PD to the power supply circuit (power supply potential VDD).

Furthermore, as illustrated in FIG. 3, in the light receiving element 10, one of sources and drains of the distribution transistors VG1 and VG2 is electrically connected to the photodiode PD, and another of the sources and the drains of the distribution transistors VG1 and VG2 is electrically connected to the charge accumulation units MEM1 and MEM2, respectively. The distribution transistors VG1 and VG2 can then be brought into a conductive state according to a voltage applied to gates thereof (a first distribution gate and a second distribution gate), and transfer the charge accumulated in the photodiode PD to the charge accumulation units MEM1 and MEM2, respectively.

That is, by changing the voltages applied to the gates of the distribution transistors VG1 and VG2 at different timings, the charge accumulated in the photodiode PD can be distributed to one of the two charge accumulation units MEM1 and MEM2. In other words, it can be said that the two charge accumulation units MEM1 and MEM2 share the one photodiode PD.

As illustrated in FIG. 3, in the light receiving element 10, one of sources and drains of the transfer transistors TG1 and TG2 is electrically connected to another of the sources and the drains of the distribution transistors VG1 and VG2 and the charge accumulation units MEM1 and MEM2. Furthermore, another of the sources and the drains of the transfer transistors TG1 and TG2 is electrically connected to the floating diffusion regions FD1 and FD2. The transfer transistors TG1 and TG2 can then be brought into a conductive state according to voltages applied to gates thereof (transfer gates), and transfer the charges accumulated in the charge accumulation units MEM1 and MEM2 to the floating diffusion regions FD1 and FD2. Note that since there are two charge accumulation units MEM1 and MEM2, the transfer transistors TG1 and TG2 can share the one floating diffusion region FD.

The floating diffusion regions FD1 and FD2 are electrically connected to gates of amplification transistors AMP1 and AMP2 that convert (amplify) charges into voltages and that output the voltages as signals (pixel signals). One of sources and drains of the amplification transistors AMP1 and AMP2 is electrically connected to one of sources and drains of selection transistors SEL1 and SEL2 that output the signals obtained by the conversion to the signal lines VSL1 and VSL2 according to selection signals. Furthermore, another of the sources and the drains of the amplification transistors AMP1 and AMP2 is electrically connected to the power supply circuit (power supply potential VDD).

Another of the sources and the drains of the selection transistors SEL1 and SEL2 is electrically connected to the signal lines VSL1 and VSL2 that transmit the converted voltages as signals, and is further electrically connected to the column signal processing circuit section 34 described above. Furthermore, gates of the selection transistors SEL1 and SEL2 are electrically connected to a selection line (not illustrated) for selecting a row to output signals, and are further electrically connected to the above-described vertical drive circuit section 32. That is, the charges accumulated in the floating diffusion regions FD1 and FD2 are converted into voltages by the amplification transistors AMP1 and AMP2 and output to the signal lines VSL1 and VSL2 under the control of the selection transistors SEL1 and SEL2.

As illustrated in FIG. 3, the floating diffusion regions FD1 and FD2 are electrically connected to one of drains and sources of the reset transistors RST1 and RST2 for resetting the accumulated charges. Gates of the reset transistors RST1 and RST2 are electrically connected to a reset signal line (not illustrated), and are further electrically connected to the above-described vertical drive circuit section 32. Furthermore, another of the drains and the sources of the reset transistors RST1 and RST2 is electrically connected to the power supply circuit (power supply potential VDD). The reset transistors RST1 and RST2 can then be brought into a conductive state according to voltages applied to the gates thereof, and reset the charges accumulated in the floating diffusion regions FD1 and FD2 (discharged to the power supply circuit (power supply potential VDD)).

Here, an operation example of the light receiving element 10 will be briefly described.

First, before light reception is started, a discharge operation for discharging charge in the photodiode PD is performed. That is, the charge discharge transistors OFG1 and OFG2 are turned on, and the charge in the photodiode PD is discharged to the power supply circuit (power supply potential VDD).

Next, the light reception is started, and the distribution transistors VG1 and VG2 are controlled in such a way as to operate at different timings (for example, differentially). More specifically, in a first period, the distribution transistor VG1 is turned on, and the charge in the photodiode PD is transferred to the charge accumulation unit MEM1. On the other hand, in a second period, the distribution transistor VG2 is turned on, and the charge in the photodiode PD is transferred to the charge accumulation unit MEM2. That is, the charge generated by the photodiode PD is distributed to the charge accumulation units MEM1 and MEM2 by the distribution transistors VG1 and VG2.

Next, a discharging operation for discharging charges in the floating diffusion regions FD1 and FD2 is performed. That is, the reset transistors RST1 and RST2 are turned on, and the charges in the floating diffusion regions FD1 and FD2 are discharged to the power supply circuit (power supply potential VDD). Thereafter, the charges (ktc noise) generated in the floating diffusion regions FD1 and FD2 are removed by CDS driving.

The transfer transistors TG1 and TG2 are then turned on, and the charges accumulated in the charge accumulation units MEM1 and MEM2 are transferred to the floating diffusion regions FD1 and FD2. Then, when a light reception period ends, the light receiving elements 10 of the pixel array section 12 are sequentially selected. In the selected light receiving element 10, the selection transistors SEL1 and SEL2 are turned on. As a result, the charges accumulated in the floating diffusion regions FD1 and FD2 are output to the signal lines VSL1 and VSL2 as signals.

Note that the operation of the light receiving elements 10 according to the present embodiment is not limited to the above-described example, and, for example, order may be appropriately changed. Then, in the present embodiment, the distance to the object 800 can be obtained from a distribution ratio of the charges accumulated in the two floating diffusion regions FD1 and FD2. Hereinafter, the principle will be briefly described.

### <Principle of Distance Calculation Method Using Distance Measuring Module 1>

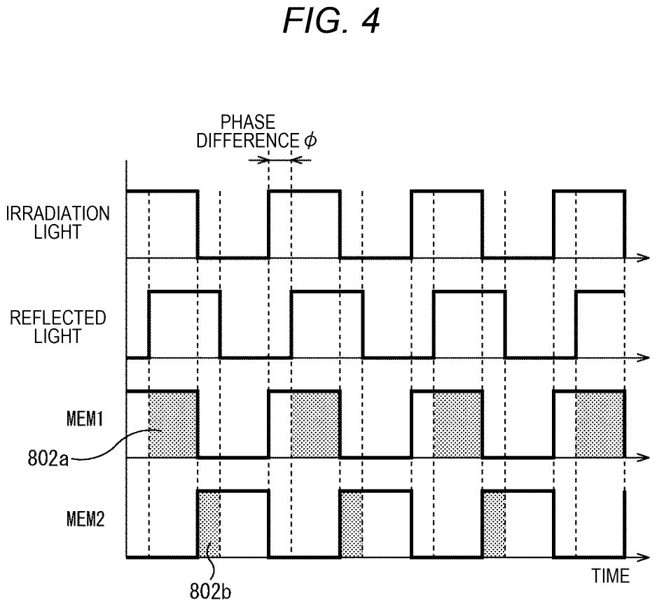

Next, the principle of the distance calculation method (indirect method) using the distance measuring module 1 will be described with reference to FIG. 4. FIG. 4 is an explanatory diagram for explaining the principle of the distance calculation method using the distance measuring module 1, and more specifically, schematically illustrates temporal variation of intensity of irradiation light and reflected light in the distance measuring module 1.

As illustrated in FIG. 4, the distance measuring module 1 radiates, from the radiation unit 20 onto the object 800, light modulated such that the intensity of light periodically varies. The radiated light is reflected by the object 800 and detected by the light receiving unit 30 of the distance measuring module 1 as reflected light. As illustrated in FIG. 4, the detected reflected light (a second stage from a top in FIG. 4) has a phase difference φ with respect to the irradiation light (a first stage from the top in FIG. 4), and the phase difference φ increases as the distance from the distance measuring module 1 to the object 800 increases and decreases as the distance from the distance measuring module 1 to the object 800 decreases.

As described above, the light receiving element 10 includes, for example, the distribution transistors VG1 and VG2 that operate differentially. Therefore, since periods during which the distribution transistors VG1 and VG2 operate do not overlap, the charge accumulated in the photodiode PD is distributed to the charge accumulation units MEM1 and MEM2 in periods of regions 802a and 802b, respectively, shown in FIG. 4 in gray. More specifically, the charge distributed to the charge accumulation units MEM1 and MEM2 is transferred to the floating diffusion regions FD1 and FD2, and finally converted into signals corresponding to areas that are integral values in the periods of the regions 802a and 802b. Therefore, as is clear from FIG. 4, a difference between the integral value of the region 802a and the integral value of the region 802b changes according to the phase difference φ of the reflected light. Therefore, the distance to the object 800 can be calculated by calculating the phase difference φ on the basis of the difference between the integral value of the region 802a and the integral value of the region 802b. Note that it is also possible to calculate the phase difference φ using not the difference between the integral values but a ratio between the integral values to calculate the distance.

### <Planar Configuration Example of Light Receiving Element>

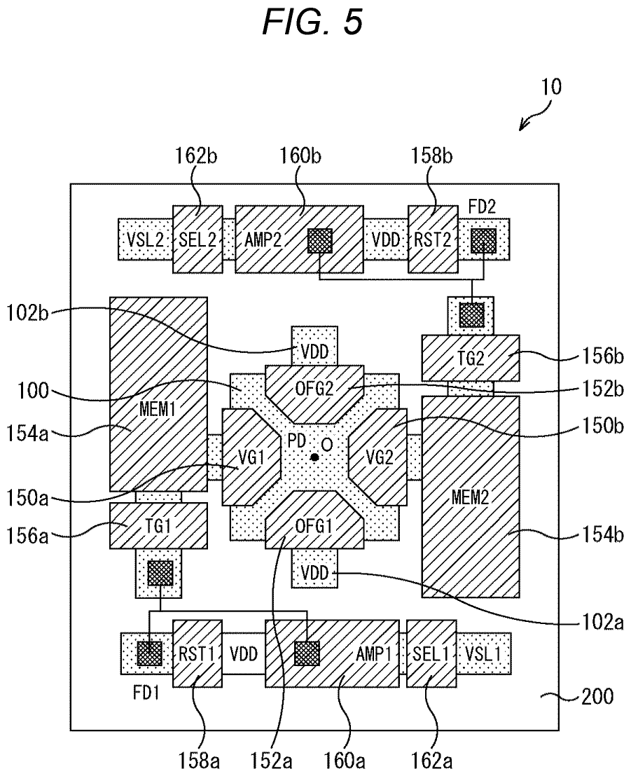

A planar configuration example of the light receiving element 10 will be described with reference to FIG. 5. FIG. 5 is a diagram illustrating a planar configuration example of the light receiving element 10 having the circuit configuration illustrated in FIG. 3, and is a view when the light receiving element 10 is viewed from above a surface of the semiconductor substrate 200. Note that the left-and-right direction in FIG. 5 corresponds to the row direction (left-and-right direction) in FIG. 2, and the up-and-down direction in FIG. 5 corresponds to the column direction (up-and-down direction) in FIG. 2.

As illustrated in FIG. 5, an N-type semiconductor region 100 is formed in the P-type semiconductor substrate 200 in a central portion of the light receiving element 10, and the N-type semiconductor region 100 constitutes a part of the photodiode (photoelectric conversion unit) PD. Furthermore, gate electrodes (a first distribution gate and a second distribution gate) 150a and 150b of the distribution transistors VG1 and VG2 are arranged in such a way as to be line-symmetric (substantially line-symmetric) with each other with respect to a center line (not illustrated) passing through a center point (center) O of the photodiode PD and extending across the light receiving element 10 in the up-and-down direction (column direction). The distribution transistors VG1 and VG2 can distribute charge generated in the photodiode PD to charge accumulation units MEM1 and MEM2 described later. Note that the gate electrodes 150a and 150b of the distribution transistors VG1 and VG2 are provided in such a way as to overlap at least a part of the N-type semiconductor region 100.

More specifically, the distribution transistor VG1 includes the gate electrode 150a, a gate insulating film (not illustrated) located between the gate electrode 150a and the semiconductor substrate 200, the N-type semiconductor region 100 as a source region, and N-type semiconductor regions 102a and 102b as drain regions. The N-type semiconductor region 100 as the source region is also used as the photodiode PD, and the N-type semiconductor regions as the drain regions is also used as the charge accumulation unit MEM1. In addition, the distribution transistor VG2 has a similar configuration as the distribution transistor VG1.

The charge accumulation units MEM1 and MEM2 are provided at positions point-symmetric (substantially point-symmetric) with each other with respect to the center point (center) O of the photodiode PD. More specifically, the charge accumulation unit MEM1 may be, for example, a metal-oxide-semiconductor (MOS) capacitor including an electrode 154a, an insulating film (not illustrated) provided below the electrode 154a, and an N-type semiconductor region (not illustrated) provided below the insulating film. In addition, the charge accumulation unit MEM2 has a similar configuration as the charge accumulation unit MEM1.

As illustrated in FIG. 5, gate electrodes (a first charge discharge gate and a second charge discharge gate) 152a and 152b of the charge discharge transistors OFG1 and OFG2 are arranged in such a way as to be line-symmetric (substantially line-symmetric) with each other with respect to a center line (not illustrated) passing through the center point O of the photodiode PD and extending across the light receiving element 10 in the left-and-right direction (row direction).

More specifically, the charge discharge transistor OFG1 includes a gate electrode 152a, a gate insulating film (not illustrated) located between the gate electrode 152a and the semiconductor substrate 200, the N-type semiconductor region 100 as the source region, and N-type semiconductor regions (not illustrated) as drain regions. The N-type semiconductor region 100 as the source region is also used as the photodiode PD. In addition, the charge discharge transistor OFG2 has a similar configuration as the charge discharge transistor OFG1.

Gate electrodes 156a and 156b of the transfer transistors TG1 and TG2 are provided at positions point-symmetric (substantially point-symmetric) with each other with respect to the center point (center) O of the photodiode PD. More specifically, the gate electrode 156a of the transfer transistor TG1 is arranged in such a way as to be adjacent to a gate insulating film (not illustrated) located between the gate electrode 156a and the semiconductor substrate 200 and the electrode 154a of the charge accumulation unit MEM1 along the up-and-down direction (column direction) in FIG. 5, and the gate electrode 156b of the transfer transistor TG2 is arranged in such a way as to be adjacent to the electrode 154b of the charge accumulation unit MEM2 along the up-and-down direction (column direction) in FIG. 5. The transfer transistors TG1 and TG2 can transfer the charges accumulated in the charge accumulation units MEM1 and MEM2 to the floating diffusion regions FD1 and FD2 described later. More specifically, the transfer transistor TG1 includes the gate electrode 156a, an N-type semiconductor region (not illustrated) as a source region, and an N-type semiconductor regions (not illustrated) as a drain region. In addition, the transfer transistor TG2 has a similar configuration as the transfer transistor TG1.

The reset transistors RST1 and RST2, the amplification transistors AMP1 and AMP2, and the selection transistors SEL1 and SEL2 are provided at positions point-symmetric (substantially point-symmetric) with each other with respect to the center point (center) O of the photodiode PD. Note that the reset transistor RST1, the amplification transistor AMP1, and the selection transistor SEL1 are arranged in such a way as to be adjacent to each other along the left-and-right direction (row direction) in FIG. 5, and the reset transistor RST2, the amplification transistor AMP2, and the selection transistor SEL2 are also arranged in such a way as to be adjacent to each other along the left-and-right direction (row direction) in FIG. 5.

More specifically, the reset transistor RST1 includes a gate electrode 158a, a gate insulating film (not illustrated) between the gate electrode 158a and the semiconductor substrate 200, an N-type semiconductor region (not illustrated) as a source region, and an N-type semiconductor region (not illustrated) as a drain region. The N-type semiconductor region as the source region is also used as the floating diffusion region FD1, and the N-type semiconductor region as the drain region is also used as the amplification transistor AMP1. The reset transistor RST2 has a similar configuration as the reset transistor RST1. In addition, the amplification transistor AMP1 includes a gate electrode 160a, a gate insulating film (not illustrated) between the gate electrode 160a and the semiconductor substrate 200, an N-type semiconductor region (not illustrated) as a drain region, and an N-type semiconductor region (not illustrated) as a source region.

The N-type semiconductor region as the drain region is also used as the drain region of the reset transistor RST1. In addition, the amplification transistor AMP2 has a similar configuration as the amplification transistor AMP1. In addition, the selection transistor SEL1 includes a gate electrode 162a, a gate insulating film (not illustrated) between the gate electrode 162a and the semiconductor substrate 200, an N-type semiconductor region (not illustrated) as a drain region, and an N-type semiconductor region (not illustrated) as a source region. The N-type semiconductor region as the drain region is also used as the source region of the amplification transistor AMP1. In addition, the selection transistor SEL2 has a similar configuration as the selection transistor SEL1.

Note that the planar configuration of the light receiving element 10 according to the present embodiment is not limited to the example illustrated in FIG. 5, and may include, for example, other elements and the like, and is not particularly limited.

### <Cross-Sectional Configuration of Light Receiving Element>

Next, a cross-sectional configuration example of the light receiving element 10 will be described with reference to FIG. 6. An upper side of FIG. 6 is a back surface side of the semiconductor substrate 200, and a lower side of FIG. 6 is a front surface side of the semiconductor substrate 200.

First, as illustrated in FIG. 6, the light receiving element 10 includes a P-type semiconductor substrate 200 such as, for example, a silicon substrate or the like. More specifically, a photodiode PD is formed in the semiconductor substrate 200 by forming N-type semiconductor regions 100a and 100b in the P-type semiconductor substrate 200.

Next, description will be given from the upper side of FIG. 6, that is, the back surface side of the semiconductor substrate 200. An on-chip lens 208 that includes a styrene-based resin, an acrylic resin, a styrene-acrylic copolymer resin, a siloxane-based resin, or the like and on which reflected light from the object 800 is incident is provided above the back surface of the semiconductor substrate 200. A planarization film 204 including, for example, silicon oxide (SiO2), silicon nitride (SiN), silicon oxynitride (SiON), or the like is provided below the on-chip lens 208. Furthermore, an antireflection film 202 including an insulating film is provided below the planarization film 204. For example, the antireflection film 202 can be formed using hafnium oxide (HfO2), aluminum oxide (Al2O3), titanium oxide (TiO2), silicon oxide, or the like, or a stack of these.

A light blocking film 206 for preventing reflected light from the object 800 from entering adjacent light receiving elements 10 is provided in a boundary region with the adjacent light receiving elements 10 above the antireflection film 202. The light blocking film 206 includes a material that blocks light, and can be formed using, for example, a metal material such as tungsten (W), aluminum (Al), or copper (Cu).

Furthermore, a pixel isolation portion 210a (deep trench isolation (DTI)) penetrating from the back surface of the semiconductor substrate 200 to the middle of the semiconductor substrate 200 along a thickness direction of the semiconductor substrate 200 is provided below the light blocking film 206. The pixel isolation portion 210a includes, for example, a trench provided in the semiconductor substrate 200 and an insulating film of silicon oxide or the like or a metal film of aluminum or the like embedded in the trench. With the pixel isolation portion 210a, it is possible to prevent incident light from entering the adjacent light receiving elements 10, and as a result, it is possible to prevent occurrence of charge crosstalk between the adjacent light receiving elements 10.

Next, the lower side of FIG. 6, that is, the front surface side of the semiconductor substrate 200, will be described. Two distribution transistors VG1 and VG2 are formed in such a way as to sandwich the N-type semiconductor region 100b. More specifically, the distribution transistors VG1 and VG2 respectively include gate electrodes 150a and 150b including, for example, polysilicon films provided on the front surface of the semiconductor substrate 200.

Furthermore, charge accumulation units MEM1 and MEM2 are provided in the semiconductor substrate 200 in such a way as to sandwich the distribution transistors VG1 and VG2 in the left-and-right direction. For example, the charge accumulation units MEM1 and MEM2 may be MOS-type capacitors formed by stacking electrodes 154a and 154b including metal films or polysilicon films, insulating film (not illustrated) including oxide films, and N-type semiconductor regions (in FIG. 6, denoted by MEM1 and MEM2).

Gate electrodes 156a and 156b of the transfer transistors TG1 and TG2 are provided on the front surface of the semiconductor substrate 200 adjacent to the charge accumulation units MEM1 and MEM2. N-type semiconductor regions illustrated as the floating diffusion regions FD1 and FD2 are formed in the semiconductor substrate 200 close to the gate electrodes 156a and 156b of the transfer transistors TG1 and TG2.

A wiring layer 300 is formed on the front surface of the semiconductor substrate 200. The wiring layer 300 includes an insulating film 302 and a metal film 304. Moreover, an electrode 306 is provided on a surface of the wiring layer 300 opposite the semiconductor substrate 200.

A substrate 400 is provided on the surface of the wiring layer 300 opposite the semiconductor substrate 200. The substrate 400 also includes an insulating film 402 and a metal film 404, and an electrode 406 is provided on the surface on a wiring layer 300 side. In the present embodiment, for example, the electrode 306 of the wiring layer 300 and the electrode 406 of the substrate 400 include copper (Cu) or the like, and can join the wiring layer 300 and the substrate 400 to each other by being in contact with each other.

Note that the cross-sectional configuration of the light receiving element 10 is not limited to the example illustrated in FIG. 6, and may include, for example, other elements and the like, and is not particularly limited.

### <Configuration Example of Light Receiving Element>

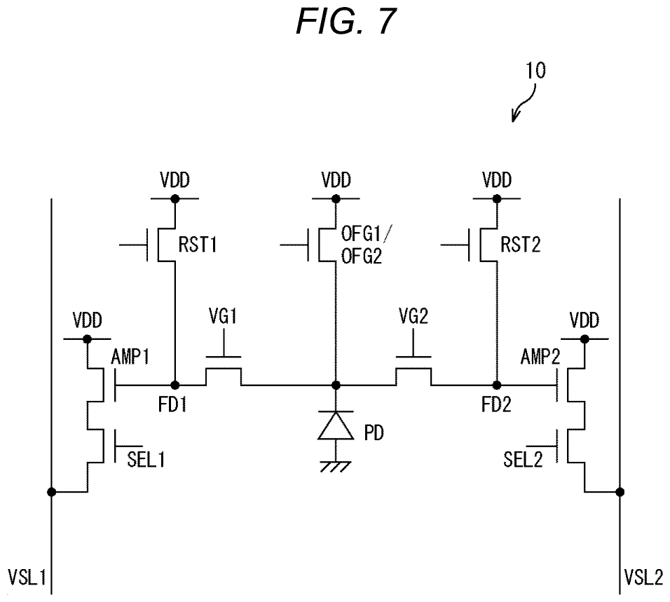

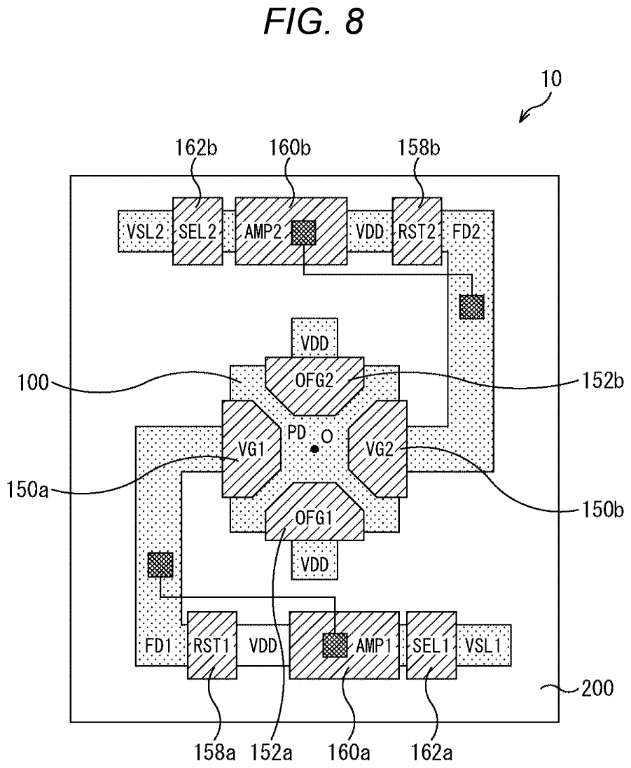

Next, another configuration example of the light receiving element 10 will be described with reference to FIGS. 7 and 8. FIG. 7 is another equivalent circuit diagram of the light receiving element 10, and FIG. 8 is a diagram illustrating a planar configuration example of the light receiving element 10 in the circuit configuration illustrated in FIG. 7.

The light receiving element 10 illustrated in FIG. 7 has a configuration in which the charge accumulation units MEM1 and MEM2 and the transfer transistors TG1 and TG2 are removed from the light receiving element 10 illustrated in FIG. 3. That is, the charge generated in the photodiode PD is directly distributed to the floating diffusion regions FD1 and FD2 by the distribution transistors VG1 and VG2.

As illustrated in FIG. 8, the gate electrodes 150a and 150b of the distribution transistors VG1 and VG2 are arranged in such a way as to be line-symmetric (substantially line-symmetric) with respect to a center line (not illustrated). Therefore, by employing a configuration in which the charge accumulation units MEM1 and MEM2 and the transfer transistors TG1 and TG2 are not provided as described above, the light receiving element 10 can be further miniaturized.

### <Yet Another Configuration Example of Light Receiving Element>

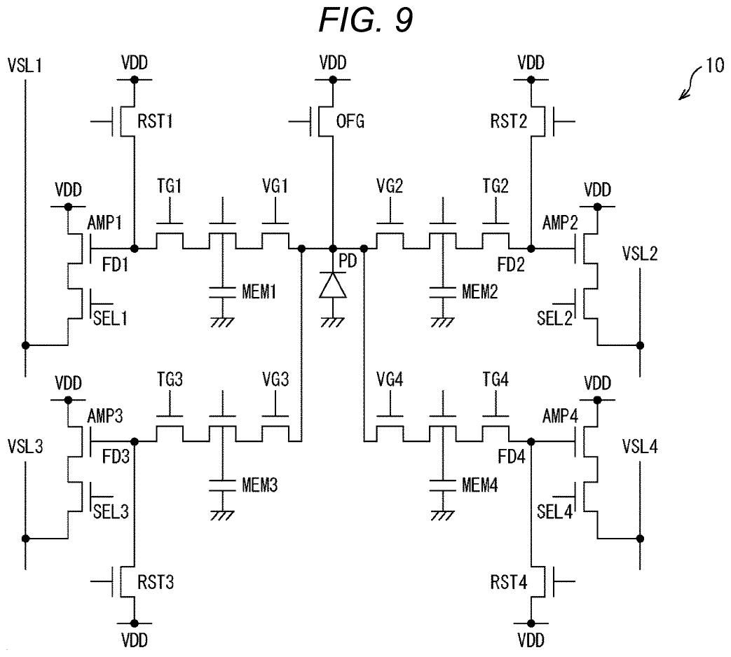

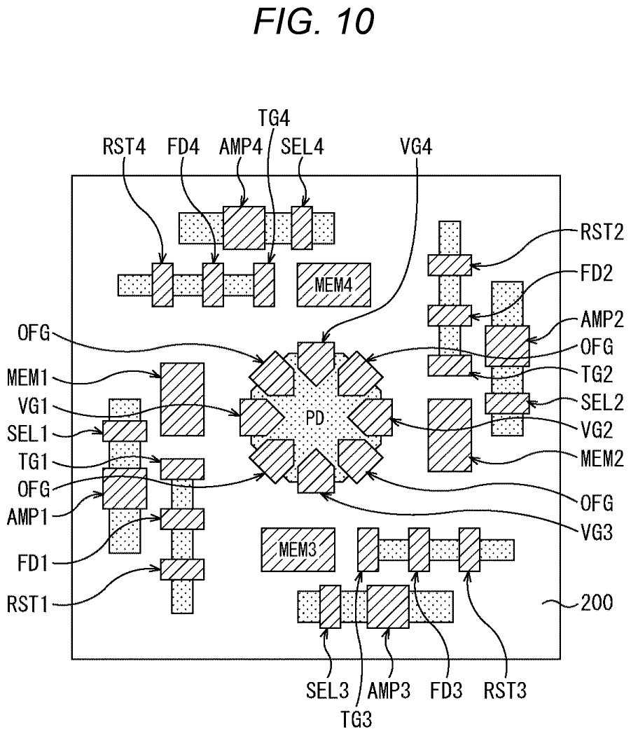

As illustrated in FIGS. 9 and 10, the present technology can also be applied to a configuration including four charge accumulation units MEM1 to MEM4. FIG. 9 is an equivalent circuit diagram of the light receiving element 10, and FIG. 10 is a diagram illustrating a planar configuration example of the light receiving element 10 having the circuit configuration illustrated in FIG. 9.

As illustrated in FIG. 9, the light receiving element 10 is provided with four combinations of a distribution transistor VG, a charge accumulation unit MEM, a transfer transistor TG, a floating diffusion region FD, a reset transistor RST, an amplification transistor AMP, and a selection transistor SEL. By providing four distribution transistors VG1, VG2, VG3, and VG4 and including four charge accumulation units MEM1, MEM2, MEM3, and MEM4, a distance measurement range can be expanded.

As illustrated in FIG. 10, the distribution transistors VG1, VG2, VG3, and VG4 of the light receiving element 10 are arranged in such a way as to be line-symmetric (substantially line-symmetric) with each other with respect to a center line passing through a center point O of the photodiode PD and extending across the light receiving element 10 in the up-and-down direction (column direction). The charge discharge transistor OFG is disposed between the distribution transistors VG1, VG2, VG3, and VG4. The charge accumulation units MEM1 to MEM4 are arranged around the distribution transistors VG1, VG2, VG3, and VG4 with the photodiode PD as the center.

### <Yet Another Configuration Example of Light Receiving Element>

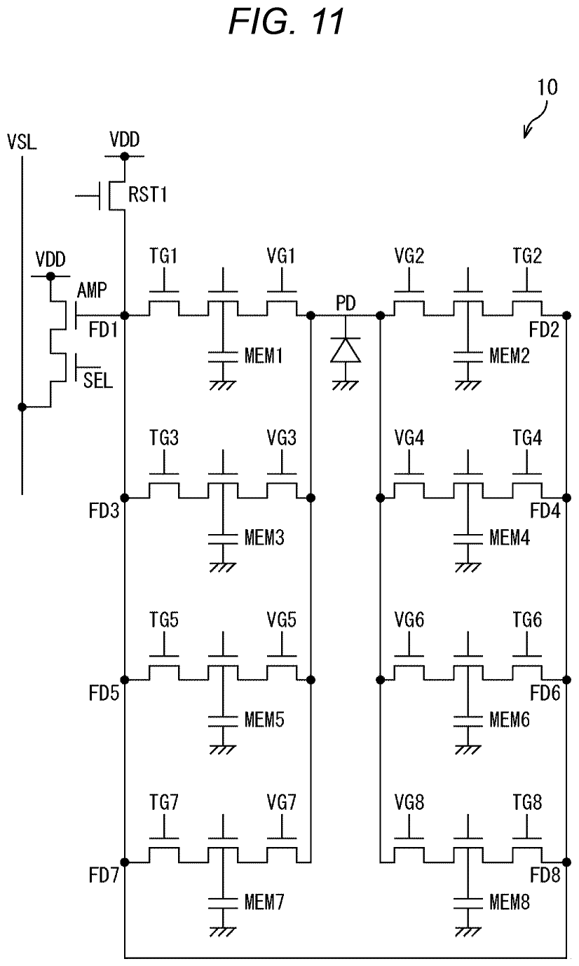

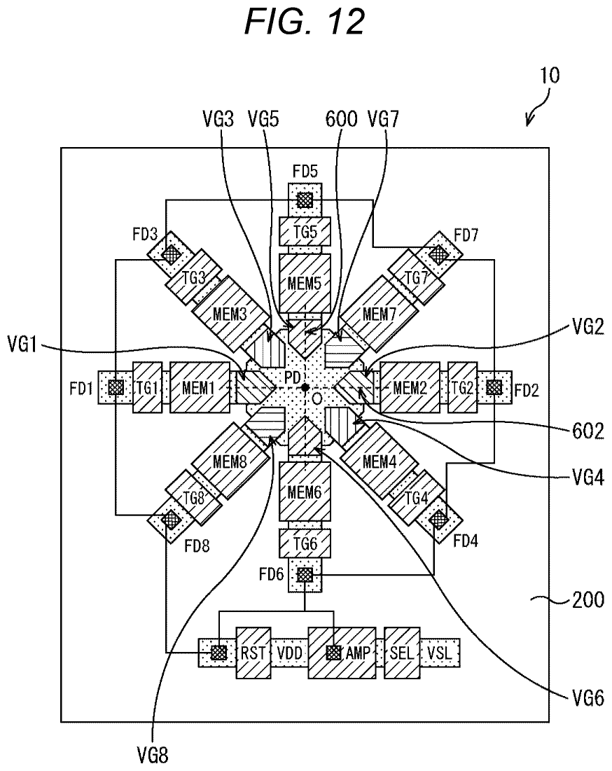

The present technology can also be applied to a configuration including eight distribution transistors VG1 to VG8 as illustrated in FIGS. 11 and 12. FIG. 11 is an equivalent circuit diagram of the light receiving element 10 including eight distribution transistors VG1 to VG8, and FIG. 12 is a diagram illustrating a planar configuration example of the light receiving element 10 in the circuit configuration illustrated in FIG. 11. By providing the eight distribution transistors VG1 to VG8, the distance measurement range can be further expanded.

As illustrated in FIG. 11, the light receiving element 10 is provided with eight combinations of a distribution transistor VG, a charge accumulation unit MEM, a transfer transistor TG, and a floating diffusion region FD. In the light receiving element 10, one reset transistor RST, one amplification transistor AMP, and one selection transistor SEL are provided.

Such a light receiving element 10 can employ a planar configuration illustrated in FIG. 12. Gate electrodes 150 of the distribution transistors VG1 to VG8 are arranged in such a way as to be line-symmetric (substantially line-symmetric) with each other with respect to a center line passing through a center point O of the photodiode PD and extending across the light receiving element 10 in the up-and-down direction (column direction). The charge accumulation units MEM1 to MEM8 are also arranged in such a way as to be line-symmetric (substantially line-symmetric) with each other with respect to the center line passing through the center point O of the photodiode PD and extending across the light receiving element 10 in the up-and-down direction (column direction).

### <Pupil Correction>

The light receiving element 10 described above has a configuration including two, four, or eight charge accumulation units MEM, and has a structure in which charge is distributed to these charge accumulation units MEM. Such light receiving elements 10 are arranged in the pixel array section 12 in an array.

Since light to the on-chip lens 208 enters at various angles with respect to the imaging surface, if a light receiving element 10 at the center of the angle of view (the center of the pixel array section 12) and a light receiving element 10 at an end of the angle of view (a peripheral portion of the pixel array section 12) have a similar structure, light cannot be efficiently collected, and a sensitivity difference might occur between the light receiving element 10 at the center of the angle of view and the light receiving element 10 at the end of the angle of view.

For example, there is a technique called pupil correction in which an optical axis of the on-chip lens 208 and an opening of the photodiode PD are aligned at the center of the imaging surface (the center of the angle of view) and a position of the photodiode PD is shifted in accordance with a direction of a principal ray toward the end of the angle of view in order to achieve a constant sensitivity without causing a difference in sensitivity between the light receiving element 10 at the center of the angle of view and the light receiving element 10 at the end of the angle of view and to maximize the sensitivity by suppressing deterioration in sensitivity of the light receiving element 10 at the end of the angle of view.

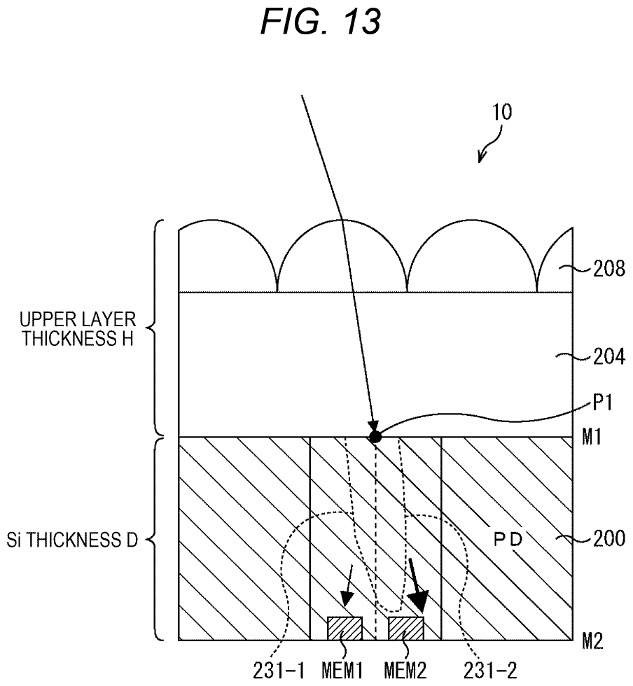

FIG. 13 illustrates a cross-sectional configuration example of a light receiving element 10 subjected to the pupil correction at an end of the angle of view. FIG. 13 illustrates the on-chip lens 208, the planarization film 204, and the semiconductor substrate 200 (photodiode PD) in the cross-sectional configuration example of the light receiving element 10 illustrated in FIG. 6, and illustrates charge accumulation units MEM1 and MEM2 formed on a bottom surface of the semiconductor substrate 200 in the drawing. In the light receiving element 10 arranged at the end of the angle of view, incident light is incident on the photodiode PD from an oblique direction as indicated by an arrow in FIG. 13.

In the light receiving element 10 arranged at the end of the angle of view, the center of the on-chip lens 208 and the center of the photodiode PD are at positions shifted by the amount of correction. In the example illustrated in FIG. 13, the center of the on-chip lens 208 is shifted from the center of the photodiode PD to a left side of the drawing by the amount of correction.

An interface between the planarization film 204 and the semiconductor substrate 200 is defined as an interface M1. Incident light passing through the center of the on-chip lens 208 passes through a center P1 of the photodiode PD at the interface M1. When light is incident on the photodiode PD from a central axis direction of the photodiode PD, light can be received from the central axis direction of the photodiode PD, similarly to the light receiving element 10 at the center of the angle of view.

As in the light receiving element 10 described above, in a case where a plurality of charge accumulation units MEM is included and charge generated as a result of photoelectric conversion by the photodiode PD is distributed, there is a possibility that a difference occurs in parasitic light sensitivity (PLS) between the charge accumulation units MEM if there is a difference in the distribution. Although the sensitivity of the light receiving element 10 can be equalized by pupil correction regardless of the position in the pixel array section 12, there is a possibility that a difference occurs in the distribution of charge generated as a result of photoelectric conversion by the photodiode PD when a light receiving element 10 at an end of the angle of view is viewed. This point will be further described.

A central axis P1 passing through the center P1 of the photodiode PD is indicated by a dotted line in the light receiving element 10 at the end of the angle of view illustrated in FIG. 13 and subjected to pupil correction. In addition, in FIG. 13, in order to describe spread of light in the photodiode PD, a distribution having a certain light intensity is indicated by a dotted line.

A region where incident light is distributed at a predetermined light intensity or more on a left side of the central axis P1 is defined as a region 231-1, and a region where the incident light is distributed at the predetermined light intensity or more on a right side of the central axis P1 is defined as a region 231-2. In the example illustrated in FIG. 13, since the incident light is incident from a left side of the drawing, it can be seen that a distance between the region 231-2 and the charge accumulation unit MEM2 tends to be longer than a distance between the region 231-1 and the charge accumulation unit MEM1.

In such a state, a component subjected to photoelectric conversion in a diffusion layer of the charge accumulation unit MEM and a component subjected to photoelectric conversion in a peripheral well and entering the diffusion layer of the charge accumulation unit MEM by diffusion, that is, so-called PLS, are larger in the charge accumulation unit MEM2 than in the charge accumulation unit MEM1.

That is, there is a possibility that a difference occurs between the PLS of the charge accumulation unit MEM1 and the PLS of the charge accumulation unit MEM2. In a case where distance measuring processing is performed in the distance measuring module 1 as described with reference to FIG. 4, distance measurement accuracy might deteriorate if there is a difference in PLS between the charge accumulation unit MEM1 and the charge accumulation unit MEM2.

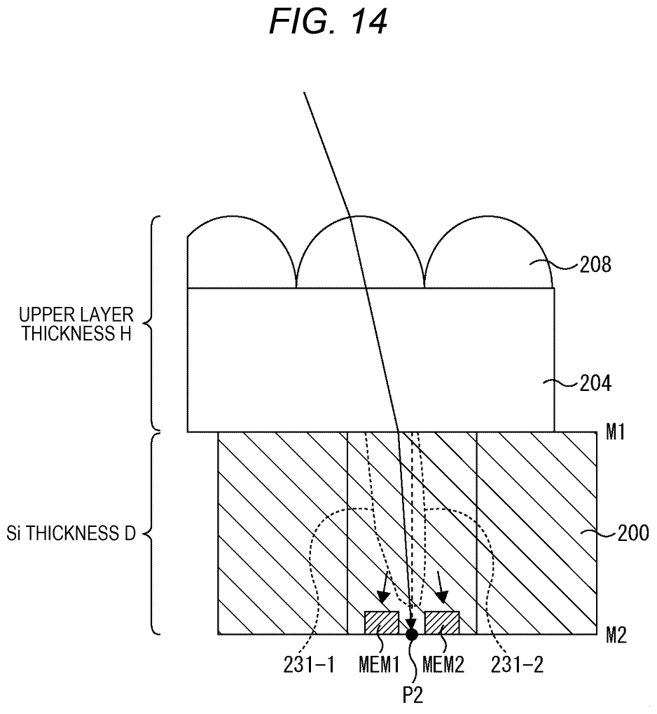

In the example illustrated in FIG. 13, the pupil correction is performed such that the principal ray enters the center P1 of the photodiode PD on a light incident surface side of the photodiode PD, but, as illustrated in FIG. 14, the pupil correction is performed such that the principal ray enters a position P2 of the photodiode PD on a surface of the photodiode PD opposite the light incident surface side.

In the light receiving element 10 illustrated in FIG. 14, the on-chip lens 208 is arranged at a position further shifted to a left side of the drawing than the on-chip lens 208 of the light receiving element 10 illustrated in FIG. 13. That is, the amount of pupil correction in the light receiving element 10 illustrated in FIG. 14 is larger than the amount of pupil correction in the light receiving element 10 illustrated in FIG. 13. As the amount of pupil correction increases, light transmitted through the center of the on-chip lens 208 is incident not at the center P1 on the incident light surface side of the photodiode PD but at a position shifted to the left side of the center P1 in the example illustrated in FIG. 13.

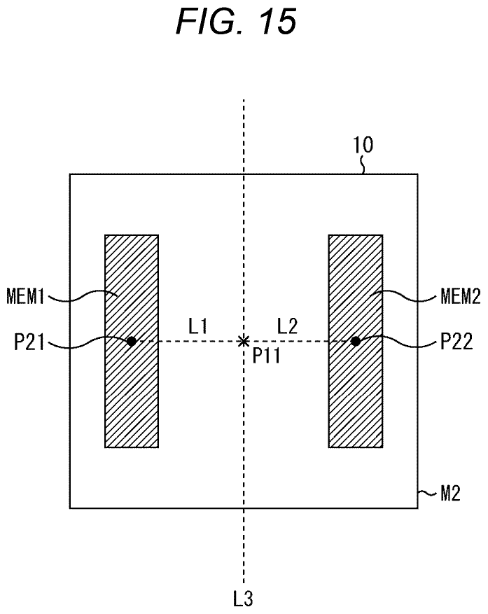

Furthermore, the light incident at the position shifted to the left side of the center P1 on the incident surface side of the photodiode PD travels toward the position P2 between the charge accumulation unit MEM1 and the charge accumulation unit MEM2. As described with reference to FIG. 15, the position P2 is a position on a line where a distance from a position of the center of gravity of the charge accumulation unit MEM1 and a distance from the position of the center of gravity of the charge accumulation unit MEM2 are the same.

The pupil correction is performed such that the principal ray is directed between the charge accumulation unit MEM1 and the charge accumulation unit MEM2, and both the region 231-1 and the region 231-2 exist at positions shifted to the left side of the drawing as illustrated in FIG. 14. As the region 231 is shifted in this manner, a distance between the region 231-1 and the charge accumulation unit MEM1 and a distance between the region 231-2 and the charge accumulation unit MEM2 become substantially the same, and it is possible to suppress occurrence of a difference in PLS.

FIG. 15 is a diagram illustrating a planar configuration example at an interface M2 between the semiconductor substrate 200 and the wiring layer 300 (not illustrated in FIGS. 6 and 14) in the light receiving element 10 of FIG. 14. In the example illustrated in FIG. 15, the charge accumulation unit MEM1 is arranged on a left side of the light receiving element 10, and the charge accumulation unit MEM2 is arranged on a right side. The center of gravity of the charge accumulation unit MEM1 is defined as a center of gravity P21, and the center of gravity of the charge accumulation unit MEM2 is defined as a center of gravity P22.

A line where a distance L1 from the center of gravity P21 of the charge accumulation unit MEM1 and a distance L2 from the center of gravity P22 of the charge accumulation unit MEM2 are equal passes through a center P11 of a line connecting the center of gravity P21 and the center of gravity P22 and becomes a perpendicular bisector L3. The point P2 (FIG. 14) is on the perpendicular bisector L3.

In a case where the charge accumulation units MEM1 and MEM2 are arranged at positions at equal distances from the center of the light receiving element 10, the perpendicular bisector L3 is a line passing through the center of the light receiving element 10. In the planar configuration example of the light receiving element 10 illustrated in each of FIGS. 5, 8, 10, and 12, the charge accumulation units MEM are arranged at positions at equal distances from the center O of the light receiving element 10. Therefore, in the case of the light receiving element 10 having such a planar configuration, the perpendicular bisector L3 is a line passing through the center of the light receiving element 10.

Furthermore, in such a case, since the center of the light receiving element 10 can also be said to be the center of gravity of the light receiving element 10, the perpendicular bisector L3 is a line passing through the center of gravity of the light receiving element 10, and can also be said to be a line serving as the center of gravity of the charge accumulation unit MEM1 and the charge accumulation unit MEM2.

Returning to the description with reference to FIG. 14, in the light receiving element 10 subjected to the pupil correction such that incident light travels to the position P2 of the interface M2, the distance between the region 231-1 and the charge accumulation unit MEM1 and the distance between the region 231-2 and the charge accumulation unit MEM2 can be made substantially the same.

In a case where charge is distributed to the charge accumulation unit MEM1 and the charge accumulation unit MEM2 in such a state, it is possible to eliminate (reduce) a difference in PLS between the charge accumulation unit MEM1 and the charge accumulation unit MEM2, and the amount of charge distributed to the charge accumulation unit MEM1 and the amount of charge distributed to the charge accumulation unit MEM2 become approximately the same. Therefore, it is possible to suppress deterioration in the distance measurement accuracy at an end of the angle of view.

### <How to Obtain Amount of Correction in Pupil Correction>

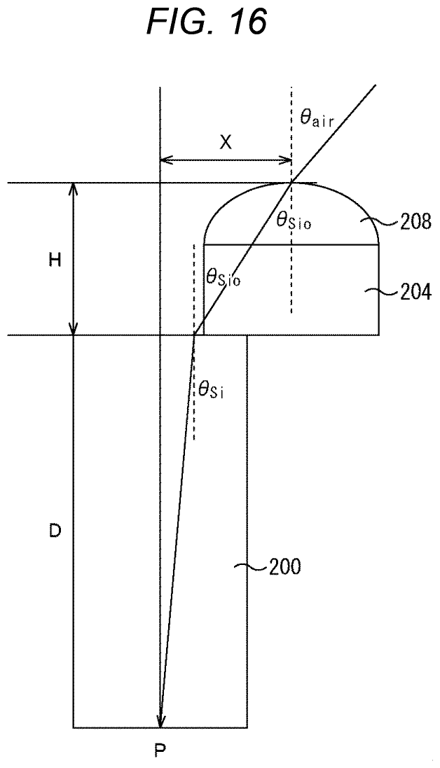

How to obtain the amount of correction in the pupil correction will be described with reference to FIG. 16. FIG. 16 is a schematic cross-sectional view of the light receiving element 10 and illustrates a state in which the semiconductor substrate 200, the planarization film 204, and the on-chip lens 208 are stacked.

Thickness of the semiconductor substrate 200 is defined as a thickness D, and a thickness (thickness of an upper layer structure of the semiconductor substrate 200) obtained by adding thickness of the planarization film 204 and thickness of the on-chip lens 208 is defined as a thickness H. In the drawing, X represents the amount of pupil correction, and represents a distance between the center of the on-chip lens 208 and the center of the semiconductor substrate 200 when viewed in plan. A case where the semiconductor substrate 200 includes silicon (Si) will be described as an example.

An incident angle of incident light with respect to the on-chip lens 208 is an angle θair, a refraction angle of light in the upper layer structure of the semiconductor substrate 200 is an angle θSiO, and a refraction angle of light in the semiconductor substrate 200 is an angle θSi. In this case, the following Expression (1) is established.

$$\begin{matrix}[ Math . 1 ] & \\ \frac{Sin {θ}_{air}}{Sin {θ}_{Si}} = \frac{n {θ}_{Si}}{n {θ}_{air}} & ( 1 )\end{matrix}$$

In Expression (1), nair denotes a refractive index of air, and nair=1. nsi denotes a refractive index of silicon, and, for example, a refractive index with respect to infrared light (940 nm) is about 3.6. In a case where the refractive index in the upper layer structure of the semiconductor substrate 200 is nSiO, nSiO is about 1.45.

The angle θSiO and the angle θSi are expressed by the following Expressions (2) and (3).

$$\begin{matrix}[ Math . 2 ] & \\ {θ}_{Si 0} = {sin}^{- 1} [ \frac{{n}_{air}}{{n}_{Si 0}} sin {θ}_{a i r} ] & ( 2 )\end{matrix}$$

$$\begin{matrix}[ Math . 3 ] & \\ {θ}_{S i} = {sin}^{- 1} [ \frac{{n}_{air}}{{n}_{S i}} sin {θ}_{a i r} ] & ( 3 )\end{matrix}$$

The amount X of pupil correction is obtained by the following Expression (4).

$$\begin{matrix}[ Math . 4 ] & \\ X = H \times tan ( {θ}_{Si 0} ) + D \times tan ( {θ}_{S i} ) = P / 2 & ( 4 )\end{matrix}$$

For reference, the following is Expression (5) for obtaining the amount of pupil correction in the case illustrated in FIG. 13, in other words, the amount of pupil correction in the case of performing the pupil correction such that incident light enters the center of the interface M1.

$$\begin{matrix}[ Math . 4 ] & \\ X = H \times tan ( {θ}_{Si 0} ) = P / 2 & ( 5 )\end{matrix}$$

Expression (4) is different from Expression (5) in that Expression (4) is obtained by adding D×tan(θsi) to Expression (5). That is, in Expression (4), the amount of pupil correction is obtained in consideration of the thickness of the semiconductor substrate 200.

As described with reference to FIG. 15, in a case where the charge accumulation unit MEM1 and the charge accumulation unit MEM2 are arranged at targets with respect to the center of the light receiving element 10, the value obtained by Expression (4) is a value half a length P of one side of the light receiving element 10.

In plan view, the on-chip lens 208 is arranged such that the center of the on-chip lens 208 and the center of the semiconductor substrate 200 are separated from each other by the amount X of correction.

Since the angle of incidence fair varies depending on a position in the angle of view, the amount of pupil correction obtained by such calculation has a value that gradually increases from the center of the angle of view toward an end of the angle of view. Note that the pupil correction may be performed only in an X-axis direction or a Y-axis direction in the pixel array section 12, or pupil correction in consideration of both the X-axis direction and the Y-axis direction may be performed.

Here, a case where two charge accumulation units MEM are provided in one light receiving element 10 has been mainly described as an example, but as described above, the present technology can also be applied to a light receiving element 10 including four or eight charge accumulation units MEM. For a light receiving element 10 including a plurality of charge accumulation units MEM, a position of the perpendicular bisector L3 or the point P2 is set according to the arrangement of the plurality of charge accumulation units MEM, and the amount of correction is set such that the principal ray travels to the perpendicular bisector L3 or the point P2.

In the case of a light receiving element 10 not including the charge accumulation unit MEM, for example, a light receiving element 10 having a structure in which charge from the photodiode PD described with reference to FIGS. 7 and 8 is directly distributed to the floating diffusion regions FD, the above-described charge accumulation units MEM may be replaced with the floating diffusion regions FD, and the amount of correction may be set.

### <Position of Light Blocking Film>

The amount of pupil correction is obtained in this manner, and the amount of pupil correction is applied to the on-chip lens 208, and the position of the center of the on-chip lens 208 is set. In a case where the light receiving element 10 includes the light blocking film 206 as illustrated in FIG. 6, the amount of correction according to the amount of correction of the on-chip lens 208 is also applied to the light blocking film 206, and the position thereof is set.

FIG. 6 will be referred to again. The light receiving element 10 illustrated in FIG. 6 is a cross-sectional configuration example of the light receiving element 10 located at the center of the angle of view. In the light receiving element 10 located at the center of the angle of view, the light blocking film 206 is arranged between the photodiodes PD and is provided such that incident light does not leak into the adjacent photodiodes PD. The light blocking film 206 is arranged on the pixel isolation portion 210a that isolates pixels from each other. In other words, it is arranged between the on-chip lenses 208.

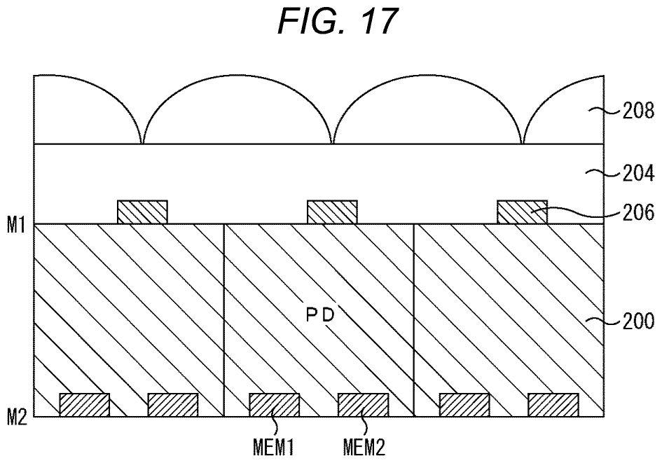

FIG. 17 is a diagram illustrating a simplified cross-sectional configuration of the light receiving element 10 illustrated in FIG. 6, and illustrates a cross-sectional configuration example of the light receiving element 10 located at an end of the angle of view. Referring to FIG. 17, each light blocking film 206 is located between on-chip lenses 208. The amount of pupil correction obtained as described above is applied to the on-chip lenses 208, and the centers of the on-chip lenses 208 are arranged at positions shifted from the centers of photodiodes PD.

Similarly to the application of the amount of pupil correction to the on-chip lenses 208, the amount of pupil correction is also applied to the light blocking films 206, and the positions thereof are shifted. In the example illustrated in FIG. 17, the light blocking films 206 are arranged the interface M1 near the centers of the photodiodes PD. Thes positions correspond to between an on-chip lens 208 and an adjacent on-chip lens 208. Furthermore, as for a relationship with positions where the charge accumulation units MEM1 and the charge accumulation units MEM2 of the photodiodes PD are arranged, each light blocking film 206 is located between the corresponding charge accumulation unit MEM1 and the corresponding charge accumulation unit MEM2 in plan view.

In the example illustrated in FIG. 17, each light blocking film 206 is located in the vicinity of the pixel center since the light blocking film 206 is located at an end of the angle of view, where the amount of pupil correction is large, but in the case of a light receiving element 10 located between the center of the angle of view and the end of the angle of view, the light blocking film 206 might be located on the charge accumulation unit MEM1 or the charge accumulation unit MEM2.

As described above, in a light receiving element 10 provided with a light blocking film 206, pupil correction is also applied to the light blocking film 206, and a position thereof is set at an appropriate position.

### <Effects>

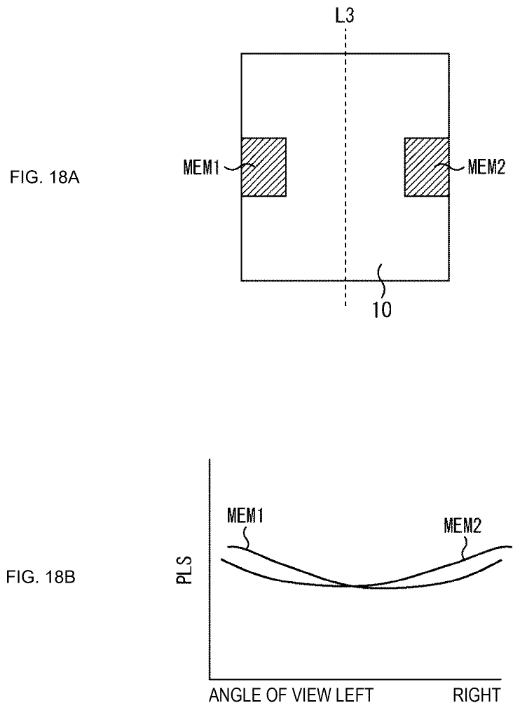

In a case where the amount of pupil correction at an end of the angle of view is obtained in this manner and the amount of pupil correction is applied, an effect illustrated in FIG. 18 can be obtained. As illustrated in A of FIG. 18, in a case where PLS is measured in a light receiving element 10 designed such that the charge accumulation unit MEM1 is on a left side of the drawing, the charge accumulation unit MEM2 is on a right side of the drawing, and the perpendicular bisector L3 as a target position to which the principal ray travels is in a longitudinal direction at the center on the interface M2 of the light receiving element 10, a result illustrated in B of FIG. 18 is obtained.

In a graph illustrated in B of FIG. 18, a vertical axis represents PLS, a horizontal axis represents the position of the light receiving element 10 within the angle of view, a left side of the drawing corresponds to a left side of the angle of view, and a right side of the drawing corresponds to a right side of the angle of view. As illustrated in B of FIG. 18, in a case where the PLS of the charge accumulation unit MEM1 and the PLS of the charge accumulation unit MEM2 on the left of the angle of view are compared, a difference is small. Although not illustrated, the difference is large in the case of a light receiving element to which the present technology is not applied, and it is understood that occurrence of a difference in PLS between the charge accumulation unit MEM1 and the charge accumulation unit MEM2 can be suppressed by applying the present technology.

Similarly, in a case where the PLS of the charge accumulation unit MEM1 and the PLS of the charge accumulation unit MEM2 on the right of the angle of view are compared with each other, the difference is small, and it is understood that occurrence of a difference in PLS between the charge accumulation unit MEM1 and the charge accumulation unit MEM2 can be suppressed by applying the present technology.

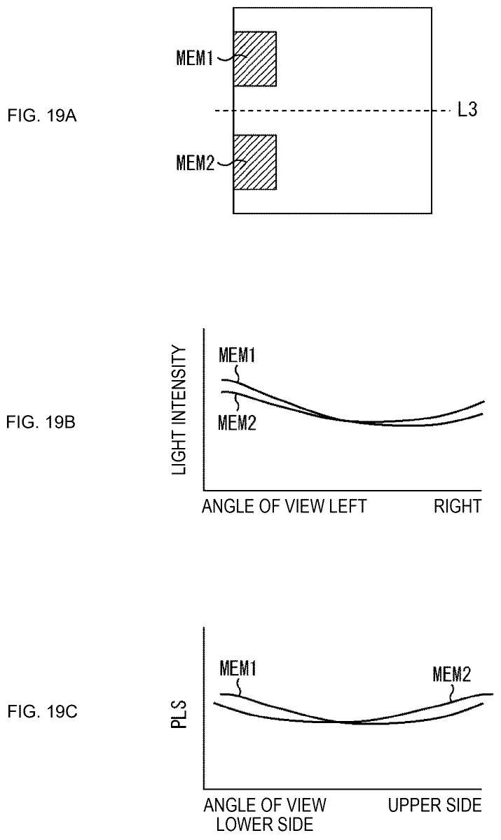

A of FIG. 19 illustrates an example in which the charge accumulation unit MEM1 and the charge accumulation unit MEM2 are arranged in the up-and-down direction. As illustrated in A of FIG. 19, in a case where PLS is measured in a light receiving element 10 designed such that the charge accumulation unit MEM1 is on an upper side of the drawing, the charge accumulation unit MEM2 is on a lower side of the drawing, and the perpendicular bisector L3 as a target position to which the principal ray travels is in a lateral direction at the center on the interface M2 of the light receiving element 10, results illustrated in B and C of FIG. 19 are obtained.

In a graph illustrated in B of FIG. 19, a vertical axis represents PLS, a horizontal axis represents the position of the light receiving element 10 within the angle of view, a left side of the drawing corresponds to a left side of the angle of view, and a right side of the drawing corresponds to a right side of the angle of view. As illustrated in B of FIG. 19, in a case where the PLS of the charge accumulation unit MEM1 and the PLS of the charge accumulation unit MEM2 on the left side of the angle of view are compared, a difference is small. Similarly, in a case where the PLS of the charge accumulation unit MEM1 and the PLS of the charge accumulation unit MEM2 on the right of the angle of view are compared with each other, the difference is small, and it is understood that occurrence of a difference in PLS between the charge accumulation unit MEM1 and the charge accumulation unit MEM2 can be suppressed by applying the present technology.

In a graph illustrated in C of FIG. 19, a left side of the drawing corresponds to lower side of the angle of view, and a right side of the drawing corresponds to an upper side of the angle of view. As illustrated in C of FIG. 19, in a case where the PLS of the charge accumulation unit MEM1 and the PLS of the charge accumulation unit MEM2 on the upper side of the angle of view are compared, a difference is small. Although not illustrated, the difference in the upper side of the angle of view is large in the case of a light receiving element to which the present technology is not applied, and therefore it is understood that occurrence of a difference in PLS between the charge accumulation unit MEM1 and the charge accumulation unit MEM2 can be suppressed by applying the present technology.

Similarly, in a case where the PLS of the charge accumulation unit MEM1 and the PLS of the charge accumulation unit MEM2 on the lower side of the angle of view are compared with each other, the difference is small, and it is understood that occurrence of a difference in PLS between the charge accumulation unit MEM1 and the charge accumulation unit MEM2 can be suppressed by applying the present technology.

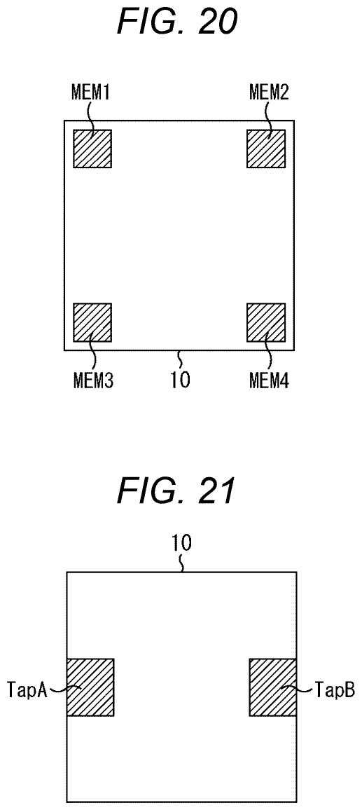

FIG. 20 illustrates an example in which four charge accumulation units MEM1 to MEM4 are arranged at four corners of the light receiving element 10. In a case where the distance measurement is performed by the light receiving element 10 including the four charge accumulation units MEM1 to MEM4, it is possible to use a fact that a relationship of

Charge accumulation unit MEM1+charge accumulation unit MEM4≈charge accumulation unit MEM2+charge accumulation unit MEM3
holds, and the difference in PLS can be canceled by adjusting the addition.

Furthermore, since it is possible to suppress occurrence of a difference in PLS in any combination of the charge accumulation unit MEM1, the charge accumulation unit MEM2, the charge accumulation unit MEM3, and the charge accumulation unit MEM4 by applying the present technology, it is possible to perform an operation using a combination other than the signal addition combinations such as the charge accumulation unit MEM1+the charge accumulation unit MEM4 and the charge accumulation unit MEM2+the charge accumulation unit MEM3 described above, that is, for example, combinations such as the charge accumulation unit MEM1+the charge accumulation unit MEM2 and the charge accumulation unit MEM3+charge accumulation unit MEM4.

### <Application to I Pixels and Q Pixels>

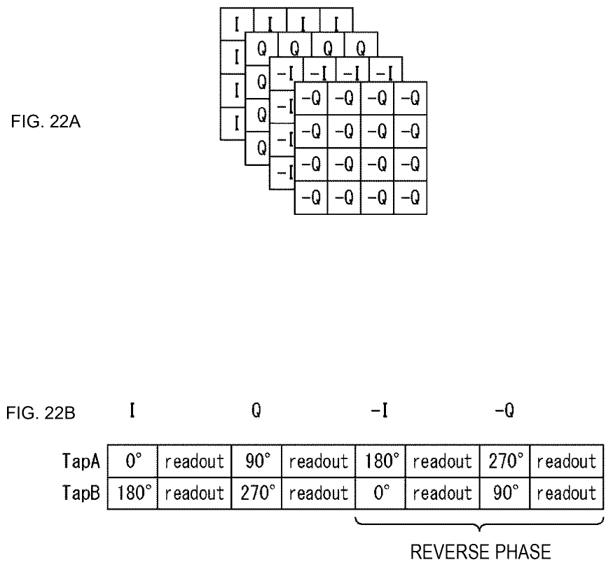

I pixels and the Q pixels will be further described. As illustrated in FIG. 21, a case where the light receiving element 10 includes a tap A and a tap B will be described as an example. The tap A includes the charge accumulation unit MEM1, and the tap B includes the charge accumulation unit MEM2.

In a case where the light receiving element 10 includes the tap A and the tap B, a detection signal having a phase of 0° is acquired in the tap A, and a detection signal having a phase of 180° is acquired in the tap B. An in-phase component with respect to a modulated wave of light will be referred to as I pixel data, and pixels for acquiring the I pixel data will be referred to as I pixels.

In a case where the light receiving element 10 includes the tap A and the tap B, a detection signal having a phase of 90° is acquired in the tap A, and a detection signal having a phase of 270° is acquired in the tap B. As described above, a quadrature component with respect to a modulated wave of light will be referred to as Q pixel data, and pixels for acquiring the Q pixel data will be referred to as Q pixels.

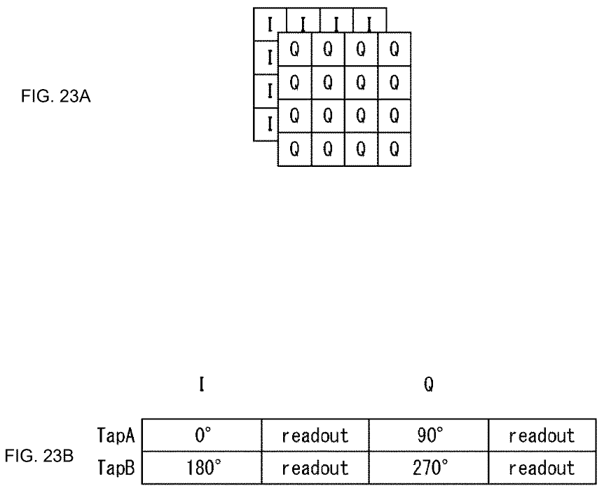

A distance measuring method in the light receiving element 10 including the two taps illustrated in FIG. 21 will be described. A method called a two-tap four-phase will be described as an example with reference to FIG. 22. A case where a distance to a predetermined object is measured using irradiation light having four phase differences with two taps or by receiving light with four phase differences will be referred to as two-tap four-phase.

In the light receiving element 10 including the tap A and the tap B, first, exposure for acquiring a phase signal having a phase of 0° is performed in the tap A, and then the phase signal having the phase of 0° is read. On the other hand, in the tap B, exposure for acquiring a phase signal having a phase of 180° is performed, and then the phase signal having the phase of 180° is read. The light receiving element 10 thus functions as an I pixel, and first accumulation and reading are performed to acquire a first frame.

Next, in the tap A, exposure for acquiring a phase signal having a phase of 90° is performed, and then the phase signal having the phase of 90° is read. On the other hand, in the tap B, exposure for acquiring a phase signal having a phase of 270° is performed, and then the phase signal having the phase of 270° is read. The light receiving element 10 thus functions as a Q pixel, and second accumulation and reading are performed to acquire a second frame.

Next, in the tap A, exposure for acquiring a phase signal having a phase of 180° is performed, and then the phase signal having the phase of 180° is read. On the other hand, in the tap B, exposure for acquiring a phase signal having a phase of 0° is performed, and then the phase signal having the phase of 0° is read. The light receiving element 10 thus functions as a −I pixel, and third accumulation and reading are performed to acquire a third frame.

Next, in the tap A, exposure for acquiring a phase signal having a phase of 270° is performed, and then the phase signal having the phase of 270° is read. On the other hand, in the tap B, exposure for acquiring a phase signal having a phase of 90° is performed, and then the phase signal having the phase of 90° is read. The light receiving element 10 thus functions as a −Q pixel, and fourth accumulation and reading are performed to acquire a fourth frame.

In order to generate one distance measurement image, accumulation and reading are performed four times. In this case, the third and fourth frames acquired by causing the light receiving element 10 to function as a −I pixel and a −Q pixel are acquired in order to cancel a mismatch between the taps, that is, the difference in PLS between the charge accumulation unit MEM1 and the charge accumulation unit MEM2 described above. By using the present technology, it is possible to suppress occurrence of a difference in PLS between the charge accumulation unit MEM1 and the charge accumulation unit MEM2, and it is not necessary to acquire a frame for canceling such a mismatch between taps.

That is, one distance measurement image can be generated through processing illustrated in FIG. 23. In the light receiving element 10 including the tap A and the tap B, first, exposure for acquiring a phase signal having a phase of 0° is performed in the tap A, and then the phase signal having the phase of 0° is read. On the other hand, in the tap B, exposure for acquiring a phase signal having a phase of 180° is performed, and then the phase signal having the phase of 180° is read. The light receiving element 10 thus functions as an I pixel, and first accumulation and reading are performed to acquire a first frame.

Next, in the tap A, exposure for acquiring a phase signal having a phase of 90° is performed, and then the phase signal having the phase of 90° is read. On the other hand, in the tap B, exposure for acquiring a phase signal having a phase of 270° is performed, and then the phase signal having the phase of 270° is read. The light receiving element 10 thus functions as a Q pixel, and second accumulation and reading are performed to acquire a second frame.

When the two frames are acquired, one distance measurement image can be generated. Since it is not necessary to acquire a reversed-phase frame, it is possible to shorten the time required to generate one distance measurement image.

### <Configuration Example of Electronic Device>

The light receiving element 10 can be applied not only to the distance measuring module as described above but also to various electronic devices including, for example, imaging devices such as a digital still camera and a digital video camera having a distance measuring function, and smartphones having a distance measuring function.

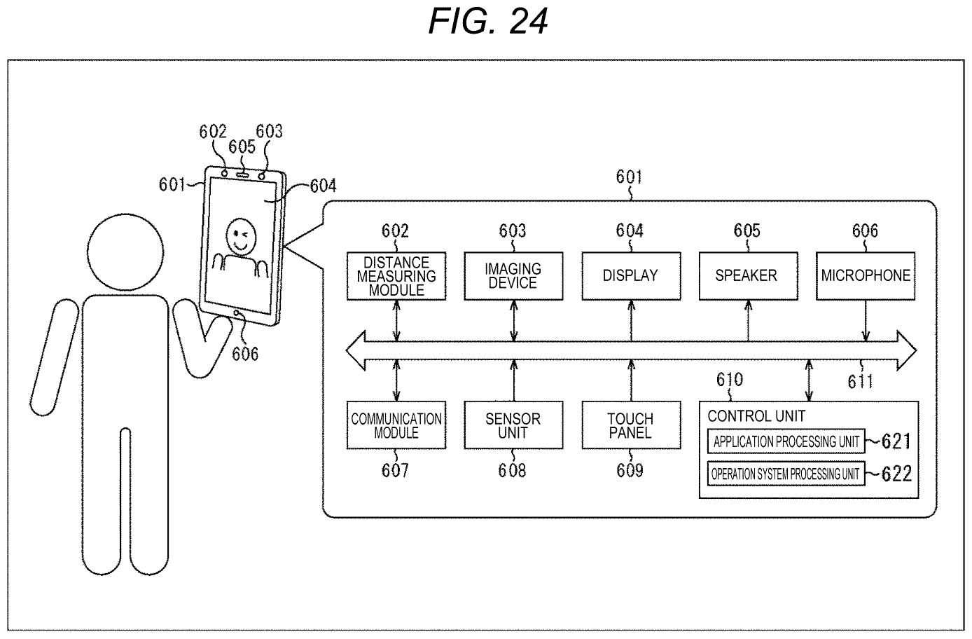

FIG. 24 is a block diagram illustrating a configuration example of a smartphone as an electronic device to which the present technology is applied.

As illustrated in FIG. 24, a smartphone 601 includes a distance measuring module 602, an imaging device 603, a display 604, a speaker 605, a microphone 606, a communication module 607, a sensor unit 608, a touch panel 609, and a control unit 610 connected to each other through a bus 611. Furthermore, the control unit 610 has functions as an application processing unit 621 and an operation system processing unit 622 when a CPU executes a program.

The distance measuring module 1 in FIG. 1 is applied to the distance measuring module 602. For example, the distance measuring module 602 is arranged on a front surface of the smartphone 601, and performs distance measurement for a user of the smartphone 601, so that a depth value of a surface shape of the face, hand, finger, or the like of the user can be output as a distance measurement result.

The imaging device 603 is arranged on the front surface of the smartphone 601, and performs imaging of the user of the smartphone 601 as a subject to obtain an image in which the user is shown. Note that although not illustrated, the imaging device 603 may also be provided on a back surface of the smartphone 601.

The display 604 displays an operation screen for performing processing by the application processing unit 621 and the operation system processing unit 622, an image captured by the imaging device 603, and the like. The speaker 605 and the microphone 606 output a voice of another party and collect a voice of the user, for example, during a call using the smartphone 601.

The communication module 607 performs network communication via the Internet, a public telephone line network, a wide area communication network for a wireless mobile body such as a so-called 4G line or a 5G line, a communication network such as a wide area network (WAN) or a local area network (LAN), near field communication such as Bluetooth (registered trademark) or near field communication (NFC), or the like. The sensor unit 608 senses speed, acceleration, proximity and the like, and the touch panel 609 obtains a touch operation by the user on an operation screen displayed on the display 604.

The application processing unit 621 performs processing for providing various services by the smartphone 601. For example, the application processing unit 621 can perform processing of creating a face by computer graphics virtually reproducing the expression of the user on the basis of the depth value supplied from the distance measuring module 602 and displaying the created face on the display 604. Furthermore, the application processing unit 621 can perform processing of creating three-dimensional shape data of any three-dimensional object on the basis of the depth value supplied from the distance measuring module 602, for example.

The operation system processing unit 622 performs processing for achieving basic functions and operations of the smartphone 601. For example, the operation system processing unit 622 can perform processing of authenticating the user's face, and unlocking the smartphone 601 on the basis of the depth value supplied from the distance measuring module 602. Furthermore, the operation system processing unit 622 can perform, for example, processing of recognizing a gesture of the user on the basis of the depth value supplied from the distance measuring module 602, and processing of inputting various operations according to the gesture.

In the smartphone 601 configured as described above, the above-described distance measuring module 1 is applied as the distance measuring module 602, for example, so that processing of measuring and displaying the distance to a predetermined object, processing of creating and displaying three-dimensional shape data of the predetermined object, and the like can be performed.

### <Application Example to Endoscopic Surgery System>

The technology according to the present disclosure (present technology) can be applied to various products. For example, the technology according to the present disclosure may be applied to an endoscopic surgery system.

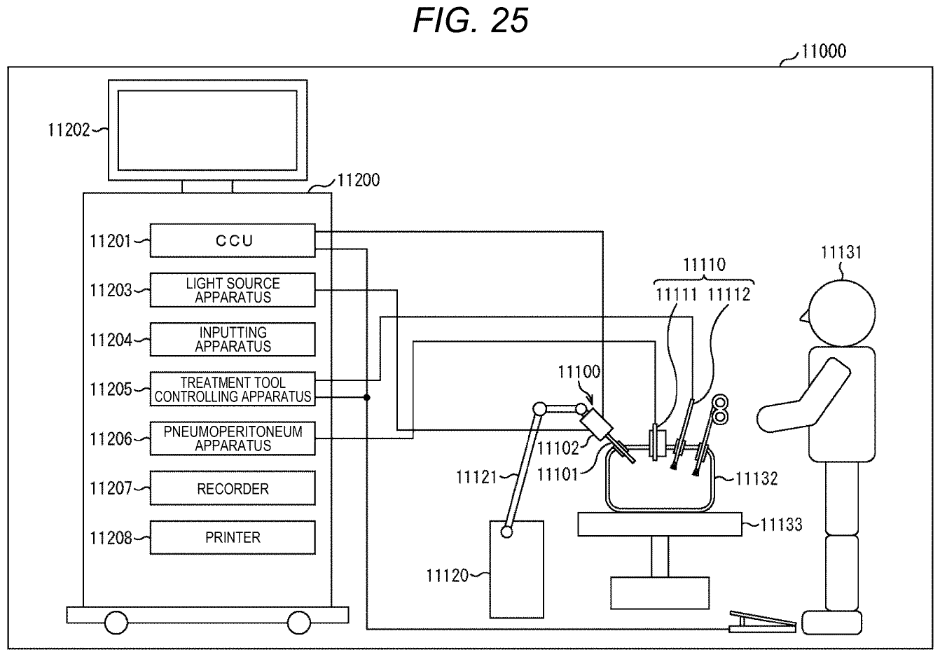

FIG. 25 is a view depicting an example of a schematic configuration of an endoscopic surgery system to which the technology according to the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

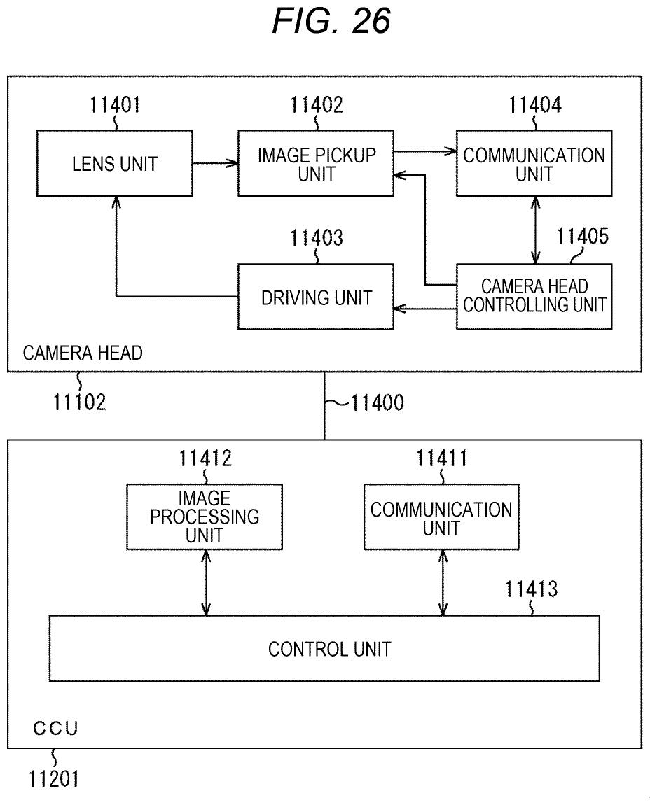

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### <Application Example to Mobile Body>

The technology according to the present disclosure (present technology) can be applied to various products. For example, the technology according to the present disclosure may be implemented in the form of a device to be mounted on a mobile body of any type, such as an automobile, an electric vehicle, a hybrid electric vehicle, a motorcycle, a bicycle, a personal mobility, an airplane, a drone, a vessel, or a robot.

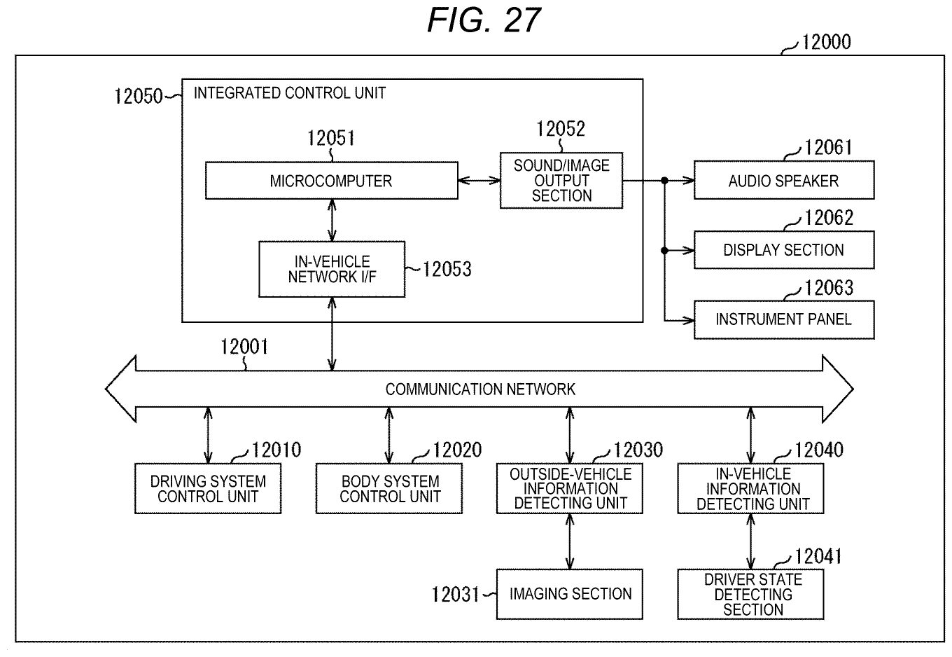

FIG. 27 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

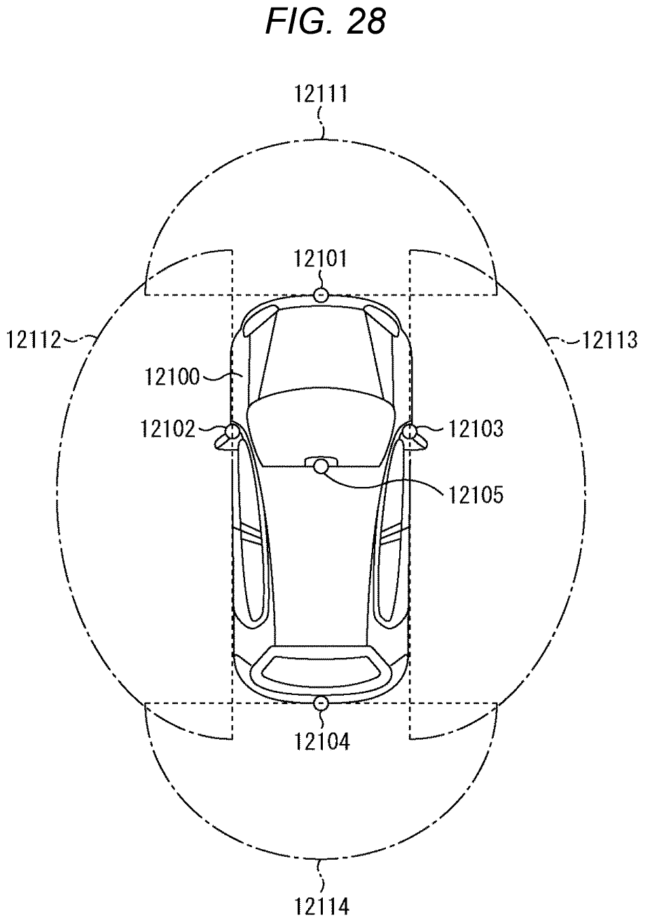

FIG. 28 is a diagram illustrating an example of installation positions of the imaging section 12031.

In FIG. 28, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 28 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

Note that the effects described in the present description are merely examples and are not limited, and other effects may be provided.

Note that embodiments of the present technology are not limited to the above-described embodiments, and various changes can be made without departing from the gist of the present technology.

Note that the present technology may also have the following configurations.

(1)

A light receiving element including:
a photoelectric conversion unit that performs photoelectric conversion;
first and second charge accumulation units that accumulate charge obtained by the photoelectric conversion unit; and
an on-chip lens that collects incident light to the photoelectric conversion unit, in which
a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.
   (2)

The light receiving element according to claim 1, in which
on an incident surface of the photoelectric conversion unit, the light incident on the center of the on-chip lens is incident on a position shifted from the center of the photoelectric conversion unit.
   (3)

The light receiving element according to (1) or (2), in which
the first charge accumulation unit and the second charge accumulation unit are arranged in contrast at the center of the photoelectric conversion unit.
   (4)

The light receiving element according to any one of (1) to (3), in which
the amount of correction is a value calculated from a thickness and a refractive index of the on-chip lens and a thickness and a refractive index of a semiconductor substrate on which the photoelectric conversion unit is formed.
   (5)

The light receiving element according to any one of (1) to (4), further including:
a light blocking film between the on-chip lens and the photoelectric conversion unit, in which
the light blocking film is positioned between the first charge accumulation unit and the second charge accumulation unit in plan view.
   (6)

The light receiving element according to any one of (1) to (5), in which
the first and second charge accumulation units are floating diffusion regions.
   (7)

The light receiving element according to any one of (1) to (6), in which
the light receiving element functions as an I pixel that acquires a signal of an in-phase component with respect to a modulated wave of light and a Q pixel that acquires a signal of a quadrature component with respect to the modulated wave of light, and
in two phases, the light receiving element acquires phase signals having a phase of 0° and a phase of 180° as the I pixel and phase signals having a phase of 90° and a phase of 270° as the Q pixel.
   (8)

A distance measuring device including:
a light emitting unit that emits irradiation light; and
a light receiving element that receives reflected light, which is the light emitted from the light emitting unit and reflected from an object, in which
the light receiving element includes:
a photoelectric conversion unit that performs photoelectric conversion;
first and second charge accumulation units that accumulate charge obtained by the photoelectric conversion unit; and
an on-chip lens that collects incident light to the photoelectric conversion unit, and
a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.

### REFERENCE SIGNS LIST

1 Distance measuring module
2 Correlation
4 2 tap
10 Light receiving element
12 Pixel array section
20 Radiation unit
30 Light receiving unit
32 Vertical drive circuit section
34 Column signal processing circuit section
36 Horizontal drive circuit section
38 Output circuit section
40 Control section
42 Pixel drive line
44 Control circuit section
46 Horizontal signal line
48 Vertical signal line
60 Processing unit
100 N-type semiconductor region
150 Gate electrode
200 Semiconductor substrate
202 Antireflection film
204 Planarization film
206 Light blocking film
208 On-chip lens
300 Wiring layer
302 Insulating film
304 Metal film
306 Electrode
400 Substrate
402 Insulating film
404 Metal film
406 Electrode
601 Smartphone
602 Distance measuring module
603 Imaging device
604 Display
605 Speaker
606 Microphone
607 Communication module
608 Sensor unit
609 Touch panel
610 Control unit
611 Bus
621 Application processing unit
622 Operation system processing unit
800 Object

1. A light receiving element comprising:
a photoelectric conversion unit that performs photoelectric conversion;
first and second charge accumulation units that accumulate charge obtained by the photoelectric conversion unit; and
an on-chip lens that collects incident light to the photoelectric conversion unit, wherein
a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.

2. The light receiving element according to claim 1, wherein
on an incident surface of the photoelectric conversion unit, the light incident on the center of the on-chip lens is incident on a position shifted from the center of the photoelectric conversion unit.

3. The light receiving element according to claim 1, wherein
the first charge accumulation unit and the second charge accumulation unit are arranged in contrast at the center of the photoelectric conversion unit.

4. The light receiving element according to claim 1, wherein
the amount of correction is a value calculated from a thickness and a refractive index of the on-chip lens and a thickness and a refractive index of a semiconductor substrate on which the photoelectric conversion unit is formed.

5. The light receiving element according to claim 1, further comprising:
a light blocking film between the on-chip lens and the photoelectric conversion unit, wherein
the light blocking film is positioned between the first charge accumulation unit and the second charge accumulation unit in plan view.

6. The light receiving element according to claim 1, wherein
the first and second charge accumulation units are floating diffusion regions.

7. The light receiving element according to claim 1, wherein
the light receiving element functions as an I pixel that acquires a signal of an in-phase component with respect to a modulated wave of light and a Q pixel that acquires a signal of a quadrature component with respect to the modulated wave of light, and
in two phases, the light receiving element acquires phase signals having a phase of 0° and a phase of 180° as the I pixel and phase signals having a phase of 90° and a phase of 270° as the Q pixel.

8. A distance measuring device comprising:
a light emitting unit that emits irradiation light; and
a light receiving element that receives reflected light, which is the light emitted from the light emitting unit and reflected from an object, wherein
the light receiving element includes:
a photoelectric conversion unit that performs photoelectric conversion;
first and second charge accumulation units that accumulate charge obtained by the photoelectric conversion unit; and
an on-chip lens that collects incident light to the photoelectric conversion unit, and
a center of the on-chip lens and a center of the photoelectric conversion unit are separated from each other by an amount of correction set such that light incident on the center of the on-chip lens is directed to a position where a distance from a center of gravity of the first charge accumulation unit is equal to a distance from a center of gravity of the second charge accumulation unit.
